(19) United States
(12) Patent Application Publication
(10) Pub. No.: US 2026/0279474 A1
(43) Pub. Date: Sep. 17, 2026

(54) MEMORY SYSTEM

(71) Applicant: Kioxia Corporation, Tokyo (JP)

(72) Inventors: Hideki YAMADA, Yokohama (JP); Masanobu SHIRAKAWA, Chigasaki (JP)

(73) Assignee: Kioxia Corporation, Tokyo (JP)

(21) Appl. No.: 19/238,683

(22) Filed: Jun. 16, 2025

(30) Foreign Application Priority Data
Mar. 14, 2025 (JP) 2025-041524

(51) Int. Cl. G11C 16/34; G11C 16/10; G11C 16/26; G11C 16/32

(52) U.S. Cl. CPC G11C 16/3459; G11C 16/102; G11C 16/26; G11C 16/32; G11C 16/3404

(57) ABSTRACT

According to one embodiment, a memory system includes a memory device and a memory controller configured to control a write operation in the memory device. The memory device includes a memory cell array including a first memory cell and a second memory cell stacked apart each other, a word line coupled to a gate of the first memory cell and a gate of the second memory cell, a first bit line, a second bit line, and a sense amplifier module to which the first bit line and the second bit line are coupled. The write operation includes a program operation and a program verification operation. In the program verification operation, a first verification voltage of a first state corresponding to a first group including the first bit line is smaller than a second verification voltage of the first state corresponding to a second group including the second bit line.

### CROSS-REFERENCE TO RELATED APPLICATIONS

This application is based upon and claims the benefit of priority from Japanese Patent Application No. 2025-041524, filed Mar. 14, 2025, the entire contents of which are incorporated herein by reference.

### FIELD

Embodiments described herein relate generally to a memory system.

### BACKGROUND

A memory system including a NAND flash memory capable of storing data in a nonvolatile manner and a memory controller that controls the NAND flash memory is known.

### BRIEF DESCRIPTION OF THE DRAWINGS

FIG. 1 is a block diagram illustrating an example of a configuration of an information processing system including a memory system according to a first embodiment.

FIG. 2 is a block diagram illustrating an example of a configuration of a memory device included in the memory system according to the first embodiment.

FIG. 3 is a circuit diagram illustrating an example of a circuit configuration of a memory cell array included in the memory system according to the first embodiment.

FIG. 4 is a perspective view illustrating an example of a structure of a memory cell array included in the memory system according to the first embodiment.

FIG. 5 is a plan view illustrating an example of a planar layout of a memory cell array included in the memory system according to the first embodiment.

FIG. 6 is a cross-sectional view taken along line VI-VI of FIG. 5.

FIG. 7 is a cross-sectional view taken along line VII-VII of FIG. 5.

FIG. 8 is a cross-sectional view taken along line VIII-VIII in FIG. 5.

FIG. 9 is a cross-sectional view of a bit line coupling portion included in the memory system according to the first embodiment taken along an X direction.

FIG. 10 is a block diagram illustrating an example of a configuration of a sense amplifier module and a data register included in the memory system according to the first embodiment.

FIG. 11 is a circuit diagram illustrating an example of a circuit configuration of a sense amplifier unit included in the memory system according to the first embodiment.

FIG. 12 is a diagram illustrating a threshold voltage distribution and data allocation in a case where the memory cell transistor included in the memory system according to the first embodiment is an MLC capable of storing 2-bit data.

FIG. 13 is a diagram illustrating a relationship between a verification voltage of an A state and the number of program loops in the comparative embodiment.

FIG. 14 is a diagram illustrating a relationship between a verification voltage of an A state and the number of program loops in an example of the memory system according to the first embodiment.

FIG. 15 is a diagram illustrating a relationship between a threshold voltage distribution and a verification voltage for each BL group in a case where the memory cell transistor included in the memory system according to the first embodiment is an MLC.

FIG. 16 is a table illustrating an example of a group mode table included in the memory system according to the first embodiment.

FIG. 17 is a flowchart illustrating a flow of a write operation in the memory system according to the first embodiment.

FIG. 18 is a diagram illustrating an example of a command sequence of the write operation in the memory system according to the first embodiment.

FIG. 19 is a timing chart showing an example of a voltage of a selected word line in a program verification operation in the memory system according to the first embodiment.

FIG. 20 is a diagram schematically illustrating an example of grouping of bit lines in the memory system according to the first embodiment.

FIG. 21 is a diagram illustrating an example of states of latch circuits at the time of the write operation in the memory system according to the first embodiment.

FIG. 22 is a diagram illustrating an example of states of latch circuits at the time of the write operation in the memory system according to the first embodiment.

FIG. 23 is a diagram illustrating an example of states of latch circuits at the time of the write operation in the memory system according to the first embodiment.

FIG. 24 is a diagram illustrating an example of states of latch circuits at the time of the write operation in the memory system according to the first embodiment.

FIG. 25 is a diagram illustrating an example of states of latch circuits at the time of the write operation in the memory system according to the first embodiment.

FIG. 26 is a diagram illustrating an example of states of latch circuits at the time of the write operation in the memory system according to the first embodiment.

FIG. 27 is a diagram illustrating an example of states of latch circuits at the time of the write operation in the memory system according to the first embodiment.

FIG. 28 is a diagram illustrating an example of states of latch circuits at the time of the write operation in the memory system according to the first embodiment.

FIG. 29 is a diagram illustrating an example of states of latch circuits at the time of the write operation in the memory system according to the first embodiment.

FIG. 30 is a diagram illustrating an example of states of latch circuits at the time of the write operation in the memory system according to the first embodiment.

FIG. 31 is a diagram illustrating an example of states of latch circuits at the time of the write operation in the memory system according to the first embodiment.

FIG. 32 is a diagram illustrating an example of states of latch circuits at the time of the write operation in the memory system according to the first embodiment.

FIG. 33 is a diagram illustrating an example of states of latch circuits at the time of the write operation in the memory system according to the first embodiment.

FIG. 34 is a graph illustrating a relationship between a voltage of a node SEN and a sense time in a program verification operation in a memory system according to a modification of the first embodiment.

FIG. 35 is a timing chart illustrating an example of voltages of a selected word line and a control signal STB in the program verification operation in the memory system according to the modification of the first embodiment.

FIG. 36 is a block diagram illustrating an example of a configuration of a sense amplifier module and a data register included in a memory system according to a second embodiment.

FIG. 37 is a timing chart illustrating an example of voltages of a selected word line and control signals STB1 and STB2 in a program verification operation in the memory system according to the second embodiment.

FIG. 38 is a flowchart illustrating a flow of a write operation in the memory system according to the second embodiment.

FIG. 39 is a diagram illustrating an example of a command sequence of the write operation in the memory system according to the second embodiment.

FIG. 40 is a diagram illustrating an example of states of latch circuits at the time of the write operation in the memory system according to the second embodiment.

FIG. 41 is a diagram illustrating an example of states of latch circuits at the time of the write operation in the memory system according to the second embodiment.

FIG. 42 is a diagram illustrating an example of states of latch circuits at the time of the write operation in the memory system according to the second embodiment.

FIG. 43 is a diagram illustrating an example of states of latch circuits at the time of the write operation in the memory system according to the second embodiment.

FIG. 44 is a diagram illustrating an example of states of latch circuits at the time of the write operation in the memory system according to the second embodiment.

FIG. 45 is a diagram illustrating an example of states of latch circuits at the time of the write operation in the memory system according to the second embodiment.

FIG. 46 is a diagram illustrating an example of states of latch circuits at the time of the write operation in the memory system according to the second embodiment.

FIG. 47 is a timing chart illustrating an example of voltages of a selected word line and control signals STB1 and STB2 in a program verification operation in a memory system according to a modification of the second embodiment.

### DETAILED DESCRIPTION

In general, according to one embodiment, a memory system includes a memory device and a memory controller configured to control a write operation in the memory device. The memory device includes a memory cell array including a first memory cell and a second memory cell stacked apart each other above a substrate, a word line coupled to a gate of the first memory cell and a gate of the second memory cell, a first bit line coupled to the first memory cell, a second bit line coupled to the second memory cell, and a sense amplifier module to which the first bit line and the second bit line are coupled. The write operation includes a program operation and a program verification operation. In the program verification operation, a first verification voltage of a first state corresponding to a first group including the first bit line is smaller than a second verification voltage of the first state corresponding to a second group including the second bit line.

Hereinafter, embodiments will be described with reference to the drawings. In the following description, components having the same function and configuration are denoted by the same reference numerals. In addition, in a case where a plurality of components having a common reference sign is distinguished, the common reference sign is added with a suffix to be distinguished. Note that, in a case where a plurality of components does not need to be particularly distinguished, only common reference numerals are attached to the plurality of components, and no suffixes are attached thereto. Here, the suffix is not limited to a subscript or a superscript, and includes, for example, a lower case alphabet added to the end of the reference sign, an index meaning an array, and the like.

### 1. FIRST EMBODIMENT

Hereinafter, a memory system according to an embodiment will be described.

### 1.1 Configuration of Memory System

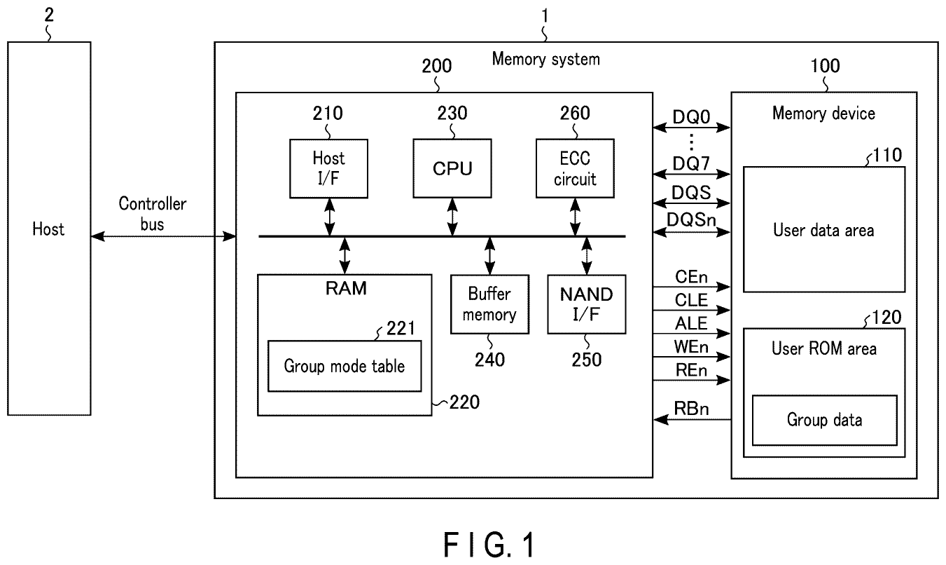

First, an example of a configuration of a memory system 1 will be described with reference to FIG. 1. FIG. 1 is a block diagram illustrating an example of a configuration of an information processing system including a memory system 1.

As illustrated in FIG. 1, the information processing system includes the memory system 1 and a host 2.

The memory system 1 is, for example, a solid state drive (SSD). The memory system 1 is coupled to the host 2 via a controller bus. The memory system 1 executes processing based on a request signal received from the host 2 or a voluntary processing request.

The host 2 is an information processing apparatus (computing device) that accesses the memory system 1. The host 2 controls the memory system 1. More specifically, for example, the host 2 requests (instructs) the memory system 1 to perform a write operation or a read operation of data (hereinafter, referred to as “user data”).

The memory system 1 includes a memory device 100 and a memory controller 200. A combination of the memory device 100 and the memory controller 200 may form one semiconductor memory device. Examples of such a semiconductor memory device include a memory card such as an SD™ card, an SSD, and the like.

The memory device 100 includes a plurality of memory cell transistors and stores data in a nonvolatile manner. The memory device 100 is, for example, a three-dimensional stacked NAND flash memory in which a plurality of memory cell transistors is three-dimensionally stacked above a semiconductor substrate. The memory device 100 includes a user data area 110 and a user ROM area 120 as memory areas. The user data area 110 is an area used for writing user data received from the host 2. The user ROM area 120 is an area in which various system data and various management data are stored. The user ROM area 120 is an area that cannot be accessed by the host 2. Each block BLK to be described later is allocated to either the user data area 110 or the user ROM area 120. The user ROM area 120 stores group data. The group data will be described later.

The memory device 100 is coupled to the memory controller 200 by a NAND bus. The memory device 100 operates based on an instruction from the memory controller 200. The 8-bit signals DQ0 to DQ7 and the clock signals DQS and DQSn are transmitted and received between the memory device 100 and the memory controller 200. Hereinafter, in a case where any of the signals DQ0 to DQ7 is not limited, it is referred to as a signal DQ. The signal DQ is, for example, data, an address, and a command. The clock signals DQS and DQSn are clock signals used at the time of inputting and outputting data. The clock signal DQSn is an inverted signal of the clock signal DQS.

In addition, the memory device 100 receives, for example, a chip enable signal CEn, a command latch enable signal CLE, an address latch enable signal ALE, a write enable signal WEn, and a read enable signal REn from the memory controller 200.

The chip enable signal CEn is a signal for enabling the memory device 100. The chip enable signal CEn is asserted at, for example, the Low (“L”) level.

The command latch enable signal CLE is a signal indicating that the signal DQ is a command. The command latch enable signal CLE is asserted at a high (“H”) level, for example.

The address latch enable signal ALE is a signal indicating that the signal DO is an address. The address latch enable signal ALE is asserted, for example, at the “H” level.

The write enable signal WEn is a signal for taking the received signal into the memory device 100. The write enable signal WEn is asserted at the “L” level, for example, every time a command and an address are received from the memory controller 200. That is, every time the write enable signal WEn is toggled, a command or an address is taken into the memory device 100.

The read enable signal REn is a signal for the memory controller 200 to read data from the memory device 100. The read enable signal REn is asserted at the “L” level, for example.

In addition, the memory device 100 transmits a ready/busy signal RBn to the memory controller 200. The ready/busy signal RBn is a signal indicating whether the memory device 100 is in a ready state or a busy state. The ready state is a state in which the memory device 100 can receive a command from the memory controller 200. The busy state is a state in which the memory device 100 cannot receive a command from the memory controller 200. For example, the “H” level of the ready/busy signal RBn indicates that the memory device 100 is in a ready state. The “L” level of the ready/busy signal RBn indicates that the memory device 100 is in a busy state.

### 1.1.1 Configuration of Memory Controller

Next, an example of a configuration of the memory controller 200 will be described with reference to FIG. 1. In response to a request (instruct) from the host 2, the memory controller 200 instructs the memory device 100 to perform a read operation, a write operation, an erase operation, and the like. In addition, the memory controller 200 manages a memory area of the memory device 100. The memory controller 200 includes, for example, a host interface circuit (host I/F) 210, an embedded memory (random access memory (RAM)) 220, a processor (central processing unit (CPU)) 230, a buffer memory 240, a NAND interface circuit (NAND I/F) 250, and an error check and correction (ECC) circuit 260.

The host interface circuit 210 is coupled to the host 2 via a controller bus and manages communication with the host 2. The host interface circuit 210 transfers the request and the data received from the host 2 to the CPU 230 and the buffer memory 240. In addition, the host interface circuit 210 transfers the data in the buffer memory 240 to the host 2 in response to an instruction from the CPU 230.

The RAM 220 is used as, for example, a work area of the CPU 230. The RAM 220 stores firmware for managing the memory device 100, various management tables, and the like. The RAM 220 stores, for example, a group mode table 221. Details of the group mode table 221 will be described later. As the RAM 220, for example, a semiconductor memory such as a static random access memory (SRAM) or a dynamic random access memory (DRAM) is used.

The CPU 230 controls the entire operation of the memory controller 200. For example, upon receiving a write request of user data from the host 2, the CPU 230 issues a command set including a command, a physical address, and write data in response to the received write request. Then, the issued command set is transferred to the memory device 100, and the memory device 100 executes the write operation based on the command set. The CPU 230 can execute each of the read operation and the erase operation as in the write operation. In addition, the CPU 230 can execute various processes for managing the memory device 100, such as wear leveling. Furthermore, the CPU 230 can execute various arithmetic processing such as data encryption processing and randomization processing.

The buffer memory 240 temporarily stores read data received by the memory controller 200 from the memory device 100. In addition, the buffer memory 240 temporarily stores user data and the like received by the memory controller 200 from the host 2. As the buffer memory 240, for example, a semiconductor memory such as a DRAM is used. The buffer memory 240 may be externally coupled to the memory controller 200 or may be integrated with the RAM 220.

The NAND interface circuit 250 is coupled to the memory device 100 via the NAND bus, and manages communication between the memory device 100 and the memory controller 200. The NAND interface circuit 250 transfers the command set issued by the CPU 230 to the memory device 100. At the time of the read operation, the NAND interface circuit 250 transfers read data received from the memory device 100 to the buffer memory 240. At the time of the write operation, the NAND interface circuit 250 transfers write data stored in the buffer memory 240 to the memory device 100.

The ECC circuit 260 is a circuit that executes the ECC process. The ECC process includes encoding and decoding of data. The encoding is an operation of generating a code word based on data. For example, the ECC circuit 260 generates an error correction code (hereinafter, referred to as “parity”) based on the user data. Then, the ECC circuit 260 imparts parity to the user data to generate a code word, that is, write data. Decoding is an operation of performing error correction of data. The ECC circuit 260 decodes data read from the memory device 100. In a case where the number of fail bits exceeds the number of error correctable bits of the ECC circuit 260, the read data cannot be decoded.

### 1.1.2 Configuration of Memory Device

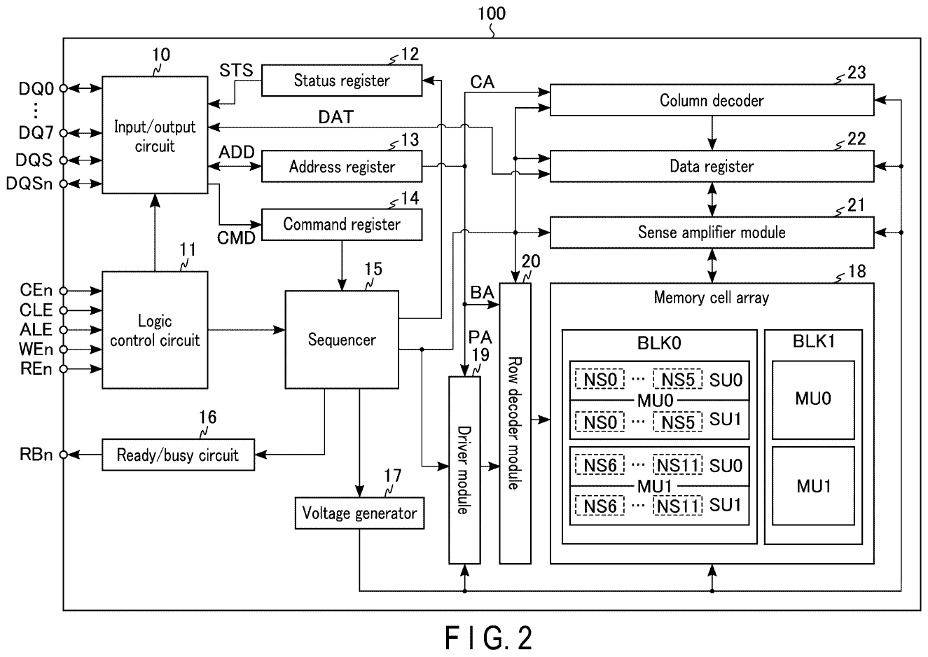

Next, an example of a configuration of the memory device 100 will be described with reference to FIG. 2. FIG. 2 is a block diagram illustrating an example of a configuration of the memory device 100. In FIG. 2, the coupling between the components is indicated by an arrow line, but the coupling between the components is not limited to the illustrated coupling.

As illustrated in FIG. 2, the memory device 100 includes, for example, an input/output circuit 10, a logic control circuit 11, a status register 12, an address register 13, a command register 14, a sequencer 15, a ready/busy circuit 16, a voltage generator 17, a memory cell array 18, a driver module 19, a row decoder module 20, a sense amplifier module 21, a data register 22, and a column decoder 23.

The input/output circuit 10 is a circuit that inputs and outputs the signal DO and the clock signals DQS and DQSn. The input/output circuit 10 is coupled to the memory controller 200 via a NAND bus. In addition, the input/output circuit 10 is coupled to the logic control circuit 11, the status register 12, the address register 13, the command register 14, and the data register 22.

The input/output circuit 10 transmits data DAT (write data) to the data register 22. The input/output circuit 10 transmits an address ADD to the address register 13. The input/output circuit 10 transmits a command CMD to the command register 14.

The input/output circuit 10 receives data DAT (read data) from the data register 22. The input/output circuit 10 receives the address ADD from the address register 13. The input/output circuit 10 receives status information STS from the status register 12.

The logic control circuit 11 is a circuit that performs logic control of the memory device 100. The logic control circuit 11 is coupled to the memory controller 200 via a NAND bus. In addition, the logic control circuit 11 is coupled to the input/output circuit 10 and the sequencer 15. The logic control circuit 11 receives, for example, a chip enable signal CEn, a command latch enable signal CLE, an address latch enable signal ALE, a write enable signal WEn, and a read enable signal REn from the memory controller 200. The logic control circuit 11 controls the input/output circuit 10 and the sequencer 15 based on a signal received from the memory controller 200.

The status register 12 is a register that temporarily stores the status information STS. The status information STS includes, for example, information for notifying the memory controller 200 whether the write operation, the read operation, the erase operation, and the like are normally ended. The status register 12 is coupled to the input/output circuit 10 and the sequencer 15. The status register 12 receives the status information STS from the sequencer 15.

The address register 13 is a register that temporarily stores the address ADD. The address ADD may include the page address PA, a block address BA, a column address CA, and the like. The address register 13 is coupled to the input/output circuit 10, the driver module 19, the row decoder module 20, and the column decoder 23. The address register 13 transmits the page address PA to the driver module 19. The address register 13 transmits the block address BA to the row decoder module 20. The address register 13 transmits the column address CA to the column decoder 23.

The command register 14 is a register that temporarily stores the command CMD. The command register 14 is coupled to the input/output circuit 10 and the sequencer 15. The command register 14 transmits the command CMD to the sequencer 15.

The sequencer 15 controls the entire operation of the memory device 100. The sequencer 15 is coupled to the input/output circuit 10, the logic control circuit 11, the status register 12, the command register 14, the ready/busy circuit 16, the voltage generator 17, the driver module 19, the row decoder module 20, the sense amplifier module 21, the data register 22, and the column decoder 23. For example, the sequencer 15 controls the status register 12, the ready/busy circuit 16, the voltage generator 17, the driver module 19, the row decoder module 20, the sense amplifier module 21, the data register 22, and the column decoder 23. The sequencer 15 executes a write operation, a read operation, an erase operation, and the like in response to the command CMD. In some embodiments, a sequencer 15 is a circuit or a component that controls timing of operations of various components of the memory device 100. In some embodiments, the sequencer 15 may operate as a control circuit or a controller. In some embodiments, the sequencer 15 is implemented as a logic circuit, ASIC, FPGA, or any combination of them. In some embodiments, the sequencer 15 may apply various voltages, pulses, or signals to various components of the memory device 100 to control timing of operations of the components of the memory device 100 as described herein.

The ready/busy circuit 16 is a circuit that transmits the ready/busy signal RBn. The ready/busy circuit 16 generates a ready/busy signal RBn based on the operation state of the sequencer 15. The ready/busy circuit 16 transmits the generated ready/busy signal RBn to the memory controller 200.

The voltage generator 17 generates various voltages used for the write operation, the read operation, the erase operation, and the like under the control of the sequencer 15. The voltage generator 17 is coupled to the sequencer 15, the memory cell array 18, the driver module 19, the sense amplifier module 21, the data register 22, the column decoder 23, and the like. The voltage generator 17 supplies the generated voltages to the memory cell array 18, the driver module 19, the sense amplifier module 21, the data register 22, the column decoder 23, and the like.

The memory cell array 18 includes a plurality of blocks BLK. In the example illustrated in FIG. 2, the memory cell array 18 includes two blocks BLK0 and BLK1. The block BLK is, for example, a set of a plurality of memory cell transistors from which data is collectively erased. The block BLK can be used, for example, as a data erasing unit.

Each block BLK includes a plurality of string units SU. The string unit SU is a set of a plurality of NAND strings NS collectively selected in the write operation or the read operation. The NAND string NS includes a plurality of memory cell transistors coupled in series. In the example illustrated in FIG. 2, each block BLK includes two string units SU0 and SU1. Each string unit SU includes the NAND strings NS0 to NS11.

Each block BLK includes a plurality of memory units MU. In the example illustrated in FIG. 2, each block BLK includes two memory units MU0 and MU1. The memory unit MU is a structure including a semiconductor layers (a channel layer of the NAND string NS) stacked above and away from the semiconductor substrate. Details of the structure of the memory unit MU will be described later.

Each memory unit MU includes part of each string unit SU. In the example illustrated in FIG. 2, the memory unit MU0 includes the NAND strings NS0 to NS5 of the string units SU0 and SU1. The memory unit MU1 includes the NAND strings NS6 to NS11 of the string units SU0 and SU1.

Note that the number of blocks BLK, string units SU, NAND strings NS, and memory units MU included in the memory cell array 18 are arbitrary.

The driver module 19 is a driver that supplies voltages to the row decoder module 20. The driver module 19 is coupled to the sequencer 15, the voltage generator 17, and the row decoder module 20. The driver module 19 and the row decoder module 20 are coupled by a plurality of signal lines. The driver module 19 receives the page address PA from the address register 13. The driver module 19 applies a plurality of voltages used for the read operation, the write operation, the erase operation, and the like to the plurality of signal lines based on the page address PA.

The row decoder module 20 is a circuit that decodes the block address BA. The row decoder module 20 is coupled to the address register 13, the sequencer 15, the memory cell array 18, and the driver module 19. The row decoder module 20 receives the block address BA from the address register 13. The row decoder module 20 selects one block BLK in the memory cell array 18 based on the decoding result of the block address BA.

The sense amplifier module 21 is a circuit that writes and reads data. The sense amplifier module 21 is coupled to the address register 13, the sequencer 15, the voltage generator 17, the memory cell array 18, and the data register 22. The sense amplifier module 21 reads data from the memory cell array 18 at the time of the read operation. The sense amplifier module 21 transfers the read data to the data register 22. In addition, the sense amplifier module 21 supplies voltages corresponding to the write data received from the data register 22 to the memory cell array 18 at the time of the write operation.

The data register 22 is a register that temporarily stores write data or read data. The data register 22 is coupled to the input/output circuit 10, the sequencer 15, the voltage generator 17, the sense amplifier module 21, and the column decoder 23. The data register 22 includes a plurality of latch circuits. Each latch circuit temporarily stores write data or read data.

The column decoder 23 is a circuit that decodes the column address CA. The column decoder 23 is coupled to the address register 13, the sequencer 15, the voltage generator 17, and the data register 22. The column decoder 23 receives the column address CA from the address register 13. The column decoder 23 selects the latch circuit in the data register 22 based on the decoding result of the column address CA.

### 1.2 Circuit Configuration of Memory Cell Array

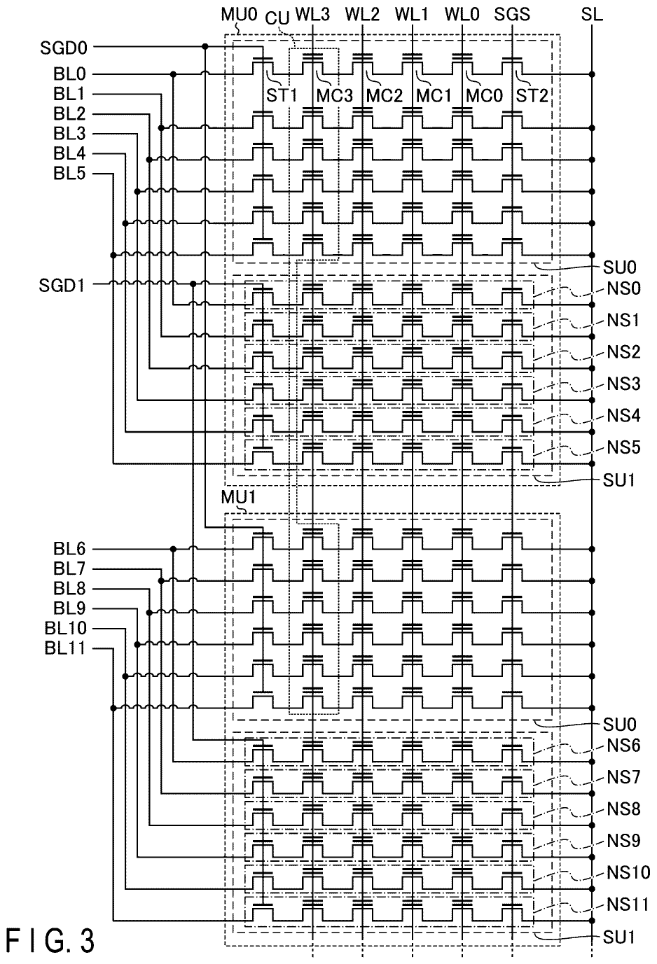

Next, an example of a circuit configuration of the memory cell array 18 will be described with reference to FIG. 3. FIG. 3 is a circuit diagram illustrating an example of a circuit configuration of the memory cell array 18. FIG. 3 illustrates an example of a circuit configuration of one block BLK in the memory cell array 18.

As shown in FIG. 3, each block BLK includes two string units SU and two memory units MU. Each string unit SU includes 12 NAND strings NS0 to NS11. The memory unit MU0 includes the NAND strings NS0 to NS5 of the string unit SU0 and the NAND strings NS0 to NS5 of the string unit SU1. The memory unit MU1 includes the NAND strings NS6 to NS11 of the string unit SU0 and the NAND strings NS6 to NS11 of the string unit SU1.

The NAND strings NS of the same number in each string unit SU are coupled to a common bit line BL. Each bit line BL is coupled to the sense amplifier module 21. For example, the NAND strings NS0 to NS11 of each string unit SU are coupled to the bit lines BL0 to BL11, respectively. More specifically, the NAND strings NS0 to NS5 included in the string units SU0 and SU1 of the memory unit MU0 are coupled to the bit lines BL0 to BL5, respectively. Further, the NAND strings NS6 to NS11 included in the string units SU0 and SU1 of the memory unit MU are coupled to the bit lines BL6 to BL11, respectively.

Each NAND string NS includes, for example, four memory cell transistors MC0 to MC3 and selection transistors ST1 and ST2. The number of memory cell transistors MC in the NAND string NS is not limited to four. In addition, the number of selection transistors ST1 and ST2 in the NAND string NS may be one or more.

The memory cell transistor MC includes a control gate and a charge storage layer, and stores data in a nonvolatile manner. The memory cell transistor MC may be a metal-oxide-nitride-oxide-silicon (MONOS) type in which an insulator is used for the charge storage layer, or may be a floating gate (FG) type in which a conductor is used for the charge storage layer. Hereinafter, a case where the memory cell transistor MC is of the MONOS type will be described.

The selection transistors ST1 and ST2 are switching elements. The selection transistors ST1 and ST2 are used to select the string unit SU in the write operation, the read operation, or the like.

In each NAND string NS, the current paths of the selection transistor ST2, the memory cell transistors MC0 to MC3, and the selection transistor ST1 are coupled in series in this order. The drain of the selection transistor ST1 is coupled to the corresponding bit line BL. The source of the selection transistor ST2 is coupled to a source line SL.

The control gates of the memory cell transistors MC0 to MC3 in the block BLK are commonly coupled to the word lines WL0 to WL3, respectively. More specifically, the control gate of each of the plurality of memory cell transistors MC0 included in the block BLK is coupled to the word line WL0. The control gate of each of the plurality of memory cell transistors MC1 included in the block BLK is coupled to the word line WL1. The control gate of each of the plurality of memory cell transistors MC2 included in the block BLK is coupled to the word line WL2. The control gate of each of the plurality of memory cell transistors MC3 included in the block BLK is coupled to the word line WL3.

In the block BLK, the gates of the plurality of selection transistors ST1 in each string unit SU are commonly coupled to one select gate line SGD. More specifically, the gates of the plurality of selection transistors ST1 included in the string unit SU0 are coupled to the select gate line SGD0. The gates of the plurality of selection transistors ST1 included in the string unit SU1 are coupled to the select gate line SGD1.

The gates of the plurality of selection transistors ST2 in the block BLK are coupled to the select gate line SGS. Note that the gates of the plurality of selection transistors ST2 in the block BLK may be coupled to different select gate lines SGS for each string unit SU, as in the select gate line SGD.

The word lines WL0 to WL3, the select gate lines SGD0 and SGD1, and the select gate line SGS are coupled to the row decoder module 20. The word lines WL0 to WL3, the select gate lines SGD0 and SGD1, and the select gate line SGS can be independently controlled by the row decoder module 20.

The bit line BL is commonly coupled to one NAND string NS of each of the plurality of string units SU of each block BLK. A plurality of bit lines BL is allocated for each memory unit MU. Each bit line BL is coupled to the sense amplifier module 21.

The source line SL is shared among the plurality of blocks BLK, for example. Note that the source line SL may be provided for each block BLK.

Hereinafter, a set of the plurality of memory cell transistors MC coupled to the common word line WL in one string unit SU will be referred to as a “cell unit CU”. In the example illustrated in FIG. 3, the memory cell transistor MC3 of each of the NAND strings NS0 to NS11 included in the string units SU0 of the memory units MU0 and MU1 is included in one cell unit CU. The page is a unit of data that is collectively written (or collectively read) to the cell unit CU. For example, in a case where the memory cell transistor MC stores 1-bit data, the storage capacity of the cell unit CU is one page. That is, the cell unit CU stores one page data. The cell unit CU may have a storage capacity of two or more pages based on the number of bits of data stored in the memory cell transistor MC. The memory cell transistor MC may be a single level cell (SLC) that stores 1-bit data or a multi level cell (MLC) that stores 2-bit data. The memory cell transistor MC may be a triple level cell (TLC) that stores 3-bit data, a quad level cell (QLC) that stores 4-bit data, or a penta level cell (PLC) that stores 5-bit data.

Hereinafter, a case where the memory cell transistor MC in the user data area 110 is an MLC and the memory cell transistor MC in the user ROM area 120 is an SLC will be described. For example, the block BLK0 is included in the user data area 110, and the block BLK1 is included in the user ROM area 120. In this case, the memory cell transistor MC of the block BLK0 is the MLC, and the memory cell transistor MC of the block BLK1 is the SLC.

Note that the number of the NAND strings NS included in each memory unit MU can be appropriately changed according to the number of stacked semiconductor layers 33 to be described later.

### 1.3 Structure of Memory Cell Array

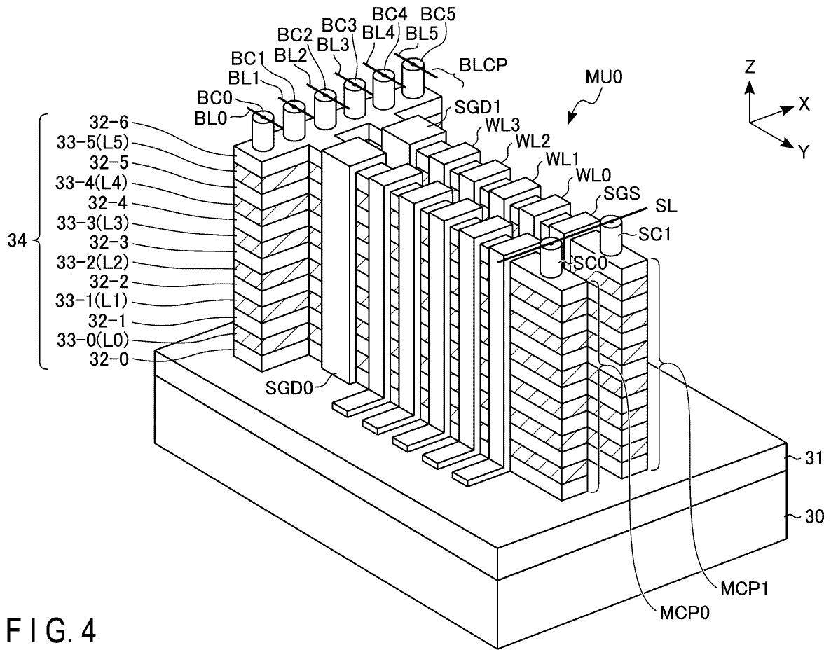

Next, an example of a structure of the memory cell array 18 will be described with reference to FIG. 4. FIG. 4 is a perspective view illustrating an example of a structure of the memory cell array 18. FIG. 4 illustrates a region including a structure corresponding to one memory unit MU0.

The X direction, the Y direction, and the Z direction used in the following description are directions crossing each other. The X direction is substantially parallel to the surface of the semiconductor substrate 30 used for forming the memory device 100 and corresponds to the direction in which the word line WL extends. The Y direction is substantially parallel to the surface of the semiconductor substrate 30 and corresponds to the direction in which the bit line BL extends. The Z direction corresponds to a vertical direction with respect to the surface of the semiconductor substrate 30. In the drawings referred to below, illustration of the configuration of the insulator layer and the like is omitted as appropriate for easy viewing of the drawings.

As illustrated in FIG. 4, the memory device 100 includes, for example, a semiconductor substrate 30, an insulator layer 31, a plurality of insulator layers 32, a plurality of semiconductor layers 33, contact plugs BC0 to BC5, and contact plugs SC0 and SC1.

The insulator layer 31 is provided on the semiconductor substrate 30. The insulator layer 31 includes, for example, silicon oxide (SiO). A structure corresponding to the memory unit MU0 is provided on the insulator layer 31. Specifically, the insulator layers 32 and the semiconductor layers 33 are alternately stacked one by one on the insulator layer 31. The insulator layer 32 includes, for example, silicon oxide (SiO). The semiconductor layer 33 is, for example, silicon doped with impurities. Hereinafter, the alternately stacked insulator layers 32 and semiconductor layers 33 are referred to as a “stacked body 34”.

In the present example, the stacked body 34 includes seven insulator layers 32 and six semiconductor layers 33. Hereinafter, the seven insulator layers 32 will be referred to as insulator layers 32-0 to 32-6 in order from the semiconductor substrate 30 side. The six semiconductor layers 33 are referred to as semiconductor layers 33-0 to 33-5 in order from the semiconductor substrate 30 side.

An interconnect layer including the semiconductor layer 33-0 is referred to as a “layer L0”. Similarly, an interconnect layer including the semiconductor layer 33-1 is referred to as a “layer L1”. An interconnect layer including the semiconductor layer 33-2 is referred to as a “layer L2”. An interconnect layer including the semiconductor layer 33-3 is referred to as a “layer L3”. An interconnect layer including the semiconductor layer 33-4 is referred to as a “layer L4”. An interconnect layer including the semiconductor layer 33-5 is referred to as a “layer L5”.

One stacked body 34 corresponds to one memory unit MU. The stacked body 34 includes a bit line coupling portion BLCP and memory cell units MCP0 and MCP1. The bit line coupling portion BLCP has a portion extending in the X direction. Each of the memory cell units MCP0 and MCP1 has a portion extending in the Y direction. One end of each of the memory cell units MCP0 and MCP1 is coupled to the bit line coupling portion BLCP. In other words, the insulator layers 32 and the semiconductor layers 33 stacked in each memory cell unit MCP are coupled to the insulator layers 32 and the semiconductor layers 33 stacked in the bit line coupling portion BLCP, respectively.

One memory cell unit MCP corresponds to one string unit SU in the memory unit MU. Specifically, the memory cell units MCP0 and MCP1 correspond to the string units SU0 and SU1, respectively. The semiconductor layers 33-0 to 33-5 of each memory cell unit MCP are provided corresponding to the NAND strings NS0 to NS5, respectively. That is, the number of NAND strings NS included in one string unit SU corresponds to the number of stacked semiconductor layers 33. In addition, the semiconductor layer 33 included in the memory cell unit MCP functions as an active area including the channel layers of the memory cell transistors MC and the selection transistors ST1 and ST2. That is, the channel layer of each NAND string NS is provided to extend in a direction (Y direction) parallel to the surface of the semiconductor substrate 30.

The bit lines BL are provided above the stacked body 34. Each bit line BL has a portion extending in the Y direction. The bit line BL is electrically coupled to the NAND string NS (the semiconductor layer 33 of the memory cell unit MCP) via the contact plug BC and the semiconductor layer 33 of the bit line coupling portion BLCP. More specifically, the bit lines BL0 to BL5 are electrically coupled to the upper faces of the contact plugs BC0 to BC5, respectively. Bottom portions of the contact plugs BC0 to BC5 are electrically coupled to the semiconductor layers 33-0 to 33-5, respectively. Each contact plug BC is electrically coupled to any one of the semiconductor layers 33 and is electrically insulated from the other semiconductor layers 33. For example, the contact plug BC0 is electrically coupled to the semiconductor layer 33-0 and is electrically insulated from the semiconductor layers 33-1 to 33-5.

The source line SL is provided above stacked body 34. Source line SL has, for example, a portion extending in the X direction. The source line SL is electrically coupled to each NAND string NS (each semiconductor layer 33 of the memory cell unit MCP) via the contact plug SC. More specifically, the source line SL is electrically coupled to the upper faces of the contact plugs SC0 and SC1. The contact plug SC0 is electrically coupled to each of the semiconductor layers 33-0 to 33-5 on the other end side of the memory cell unit MCP0. The contact plug SC1 is electrically coupled to each of the semiconductor layers 33-0 to 33-5 on the other end side of the memory cell unit MCP1.

A tunnel insulating film, a charge storage layer, and a block insulating film (hereinafter, referred to as a stacked film) not illustrated are stacked on the side face and the upper face of the stacked body 34. In addition, in the Y direction, the select gate line SGS, the word lines WL0 to WL3, and the select gate line SGD are disposed in this order from the contact plug SC side toward the contact plug BC side between the contact plug SC and the contact plug BC (bit line coupling portion BLCP). Each of the select gate line SGS and the word lines WL0 to WL3 has a portion provided to extend in the X direction so as to cover (straddle) the side face and the upper face of the stacked film provided in the memory cell unit MCP of the stacked body 34. The select gate line SGD0 has a portion provided so as to cover the side face and the upper face of the stacked film provided in the memory cell unit MCP0 of the stacked body 34. The select gate line SGD1 has a portion provided so as to cover the side face and the upper face of the stacked film provided in the memory cell unit MCP1 of the stacked body 34.

### 1.3.1 Planar Layout of Memory Cell Array

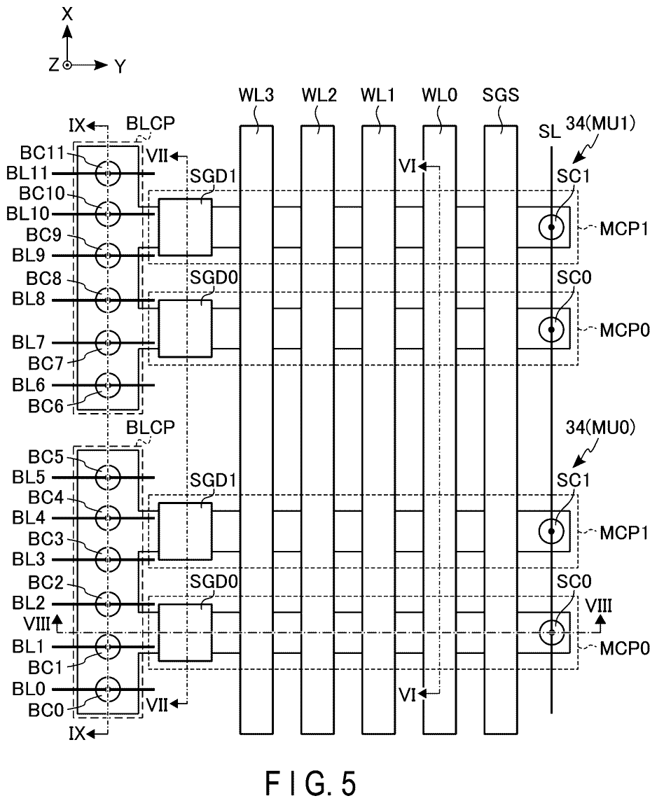

Referring now to FIG. 5, an example of a planar layout of the memory cell array 18 will be described. FIG. 5 is a plan view illustrating an example of a planar layout of the memory cell array 18. FIG. 5 illustrates a region including two adjacent memory units MU0 and MU1.

As illustrated in FIG. 5, the two stacked bodies 34 are disposed side by side in the X direction while being separated from each other.

The bit line coupling portion BLCP of the stacked body 34 corresponding to the memory unit MU0 is provided with the contact plugs BC0 to BC5 respectively coupled to the bit lines BL0 to BL5. The bit line coupling portion BLCP of the stacked body 34 corresponding to the memory unit MU1 is provided with the contact plugs BC6 to BC11 respectively coupled to the bit lines BL6 to BL11. As described above, in the present example, the bit line coupling portion BLCP of the stacked body 34 of one memory unit MU is provided with the six contact plugs BC coupled to the six bit lines BL.

The stacked body 34 corresponding to the memory unit MU0 is provided with contact plugs SC0 and SC1 coupled to the memory cell units MCP0 and MCP1, respectively. Similarly, the stacked body 34 corresponding to the memory unit MU1 is provided with contact plugs SC0 and SC1 coupled to the memory cell units MCP0 and MCP1, respectively. In this manner, each memory cell unit MCP of the stacked body 34 of one memory unit MU is provided with at least one contact plug SC coupled to the source line SL.

The select gate line SGS and the word lines WL0 to WL3 are provided in a region where a plurality of stacked bodies 34 corresponding to one block BLK are formed. Each of the select gate line SGS and the word lines WL0 to WL3 has a portion extending in the X direction and is disposed so as to overlap the plurality of stacked bodies 34. As a result, each of the select gate line SGS and the word lines WL0 to WL3 is shared among the plurality of memory units MU in the same block BLK.

The memory cell units MCP0 and MCP1 of the stacked body 34 corresponding to the memory units MU0 are provided with the select gate lines SGD0 and SGD1, respectively. Similarly, the memory cell units MCP0 and MCP1 of the stacked body 34 corresponding to the memory unit MU1 are provided with the select gate lines SGD0 and SGD1, respectively. As described above, the memory cell units MCP0 and MCP1 of one stacked body 34 are provided with the select gate lines SGD0 and SGD1, respectively. In the same block BLK, the plurality of select gate lines SGD0 are electrically coupled via contacts and interconnects (not illustrated), and the plurality of select gate lines SGD1 are electrically coupled via contacts and interconnects (not illustrated).

### 1.3.2 Cross-Sectional Structure of Memory Cell Array

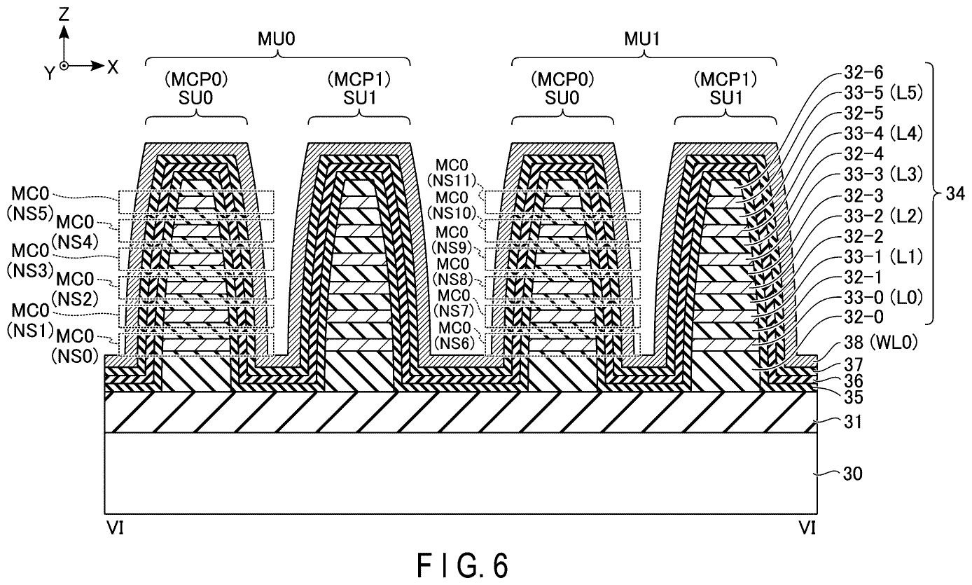

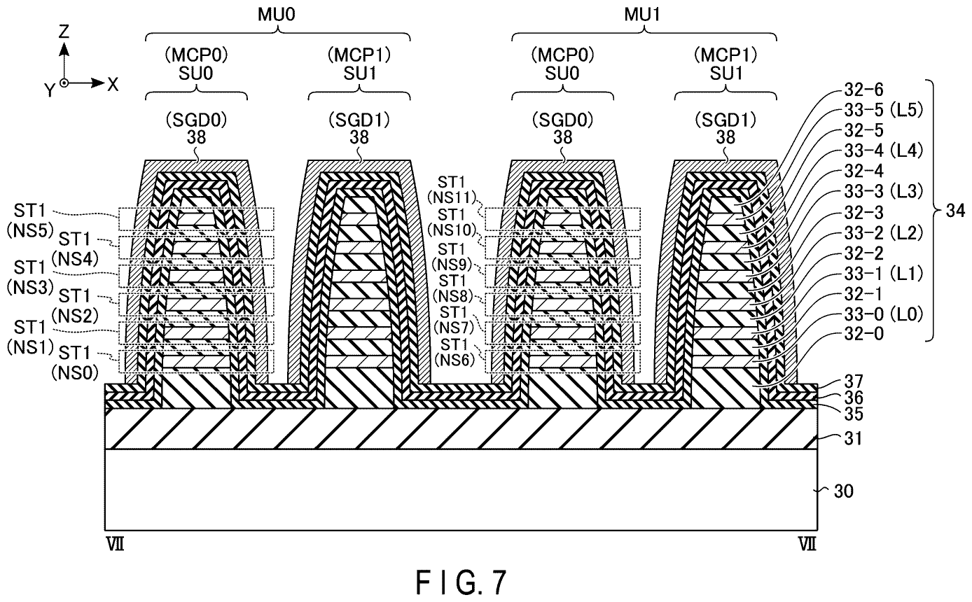

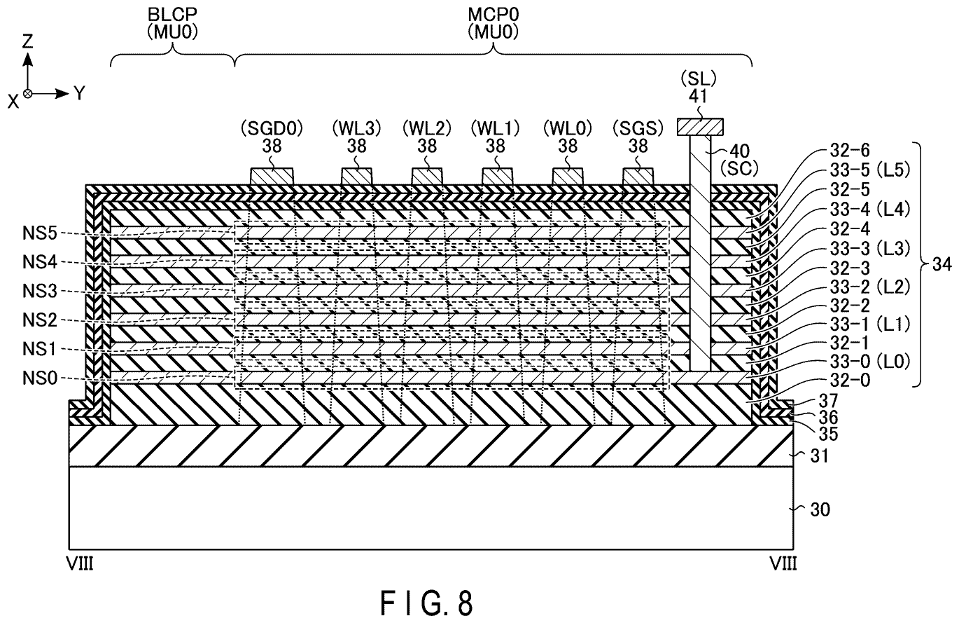

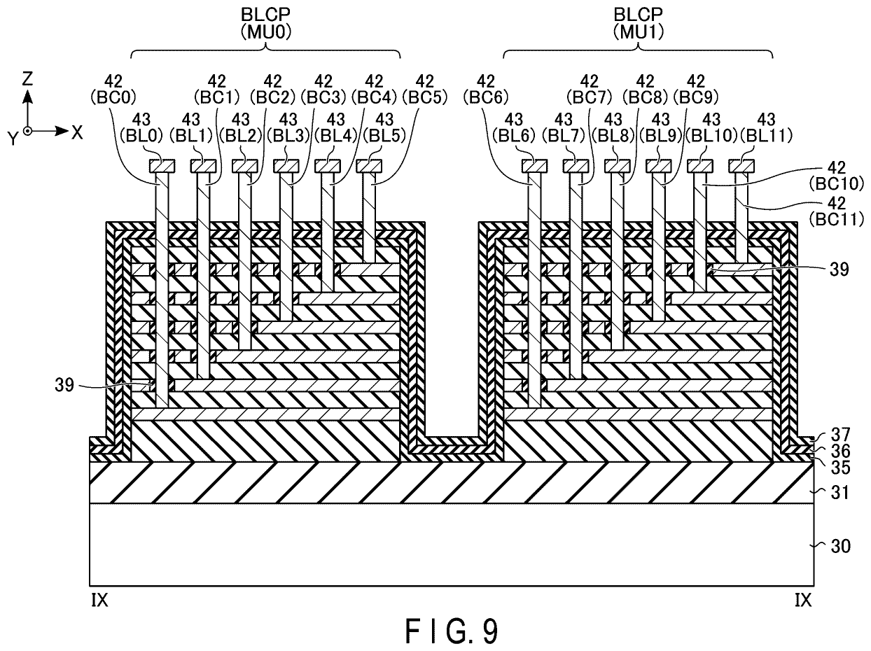

Next, an example of a cross-sectional structure of the memory cell array 18 will be described with reference to FIGS. 6 to 9. FIGS. 6 to 9 are cross-sectional views illustrating an example of a cross-sectional structure of the memory cell array 18. FIG. 6 is a cross-sectional view taken along line VI-VI in FIG. 5. FIG. 6 illustrates a cross section including the word line WL0 and along the X direction. FIG. 7 is a cross-sectional view taken along line VII-VII in FIG. 5. FIG. 7 illustrates a cross section including the select gate lines SGD0 and SGD1 and taken along the X direction. FIG. 8 is a cross-sectional view taken along line VIII-VIII in FIG. 5. FIG. 8 illustrates a cross section of the memory cell unit MCP0 of the memory unit MU0 along the Y direction. FIG. 9 is a cross-sectional view taken along line IX-IX in FIG. 5. FIG. 9 illustrates a cross section of the bit line coupling portion BLCP along the X direction.

As illustrated in FIG. 6, the memory device 100 further includes a tunnel insulating film 35, a charge storage layer 36, a block insulating film 37, and a conductive layer 38.

The tunnel insulating film 35 is continuously provided so as to cover the upper face and the side face of the stacked body 34 of each memory unit MU. In other words, the tunnel insulating film 35 is provided above the insulator layer 31 so as to straddle the stacked body 34 of each memory unit MU. The charge storage layer 36, the block insulating film 37, and the conductive layer 38 are stacked in this order on the tunnel insulating film 35.

Each of the tunnel insulating film 35 and the block insulating film 37 includes, for example, silicon oxide (SiO). The charge storage layer 36 includes, for example, silicon nitride (SiN). The conductive layer 38 contains, for example, tungsten (W). The conductive layer 38 included in the cross section shown in FIG. 6 is used as the word line WL0.

In the memory unit MU0, a portion where the semiconductor layer 33-0 and the word line WL0 in the memory cell units MCP0 and MCP1 are close to each other functions as the memory cell transistor MC0 of the NAND string NS0 included in the string units SU0 and SU1. Similarly, in the memory unit MU1, a portion where the semiconductor layer 33-0 and the word line WL0 in the memory cell units MCP0 and MCP1 are close to each other functions as the memory cell transistor MC0 of the NAND string NS6 included in the string units SU0 and SU1. That is, the memory cell transistors MC0 of the NAND strings NS0 and NS6 are included in the layer L0.

In the memory unit MU0, a portion where the semiconductor layer 33-1 in the memory cell units MCP0 and MCP1 and the word line WL0 are close to each other functions as the memory cell transistor MC0 of the NAND string NS1 included in each of the string units SU0 and SU1. Similarly, in the memory unit MU1, a portion where the semiconductor layer 33-1 in the memory cell units MCP0 and MCP1 and the word line WL0 are close to each other functions as the memory cell transistor MC0 of the NAND string NS7 included in each of the string units SU0 and SU1. That is, the memory cell transistors MC0 of the NAND strings NS1 and NS7 are included in the layer L1.

In the memory unit MU0, a portion where the semiconductor layer 33-2 in the memory cell units MCP0 and MCP1 and the word line WL0 are close to each other functions as the memory cell transistor MC0 of the NAND string NS2 included in each of the string units SU0 and SU1. Similarly, in the memory unit MU1, a portion where the semiconductor layer 33-2 in the memory cell units MCP0 and MCP1 and the word line WL0 are close to each other functions as the memory cell transistor MC0 of the NAND string NS8 included in each of the string units SU0 and SU1. That is, the memory cell transistors MC0 of the NAND strings NS2 and NS8 are included in the layer L2.

In the memory unit MU0, a portion where the semiconductor layer 33-3 in the memory cell units MCP0 and MCP1 and the word line WL0 are close to each other functions as the memory cell transistor MC0 of the NAND string NS3 included in each of the string units SU0 and SU1. Similarly, in the memory unit MU1, a portion where the semiconductor layer 33-3 in the memory cell units MCP0 and MCP1 and the word line WL0 are close to each other functions as the memory cell transistor MC0 of the NAND string NS9 included in each of the string units SU0 and SU1. That is, the memory cell transistors MC0 of the NAND strings NS3 and NS9 are included in the layer L3.

In the memory unit MU0, a portion where the semiconductor layer 33-4 in the memory cell units MCP0 and MCP1 and the word line WL0 are close to each other functions as the memory cell transistor MC0 of the NAND string NS4 included in each of the string units SU0 and SU1. Similarly, in the memory unit MU1, a portion where the semiconductor layer 33-4 in the memory cell units MCP0 and MCP1 and the word line WL0 are close to each other functions as the memory cell transistor MC0 of the NAND string NS10 included in each of the string units SU0 and SU1. That is, the memory cell transistors MC0 of the NAND strings NS4 and NS10 are included in the layer L4.

In the memory unit MU0, a portion where the semiconductor layer 33-5 in the memory cell units MCP0 and MCP1 and the word line WL0 are close to each other functions as the memory cell transistor MC0 of the NAND string NS5 included in each of the string units SU0 and SU1. Similarly, in the memory unit MU1, a portion where the semiconductor layer 33-5 in the memory cell units MCP0 and

MCP1 and the word line WL0 are close to each other functions as the memory cell transistor MC0 of the NAND string NS11 included in each of the string units SU0 and SU1. That is, the memory cell transistors MC0 of the NAND strings NS5 and NS11 are included in the layer L5.

Note that the cross-sectional structure along the X direction is similar between the cross-sectional structure including the word line WL0 and the cross-sectional structure including the other word lines WL. In addition, the cross-sectional structure along the X direction is similar between the cross-sectional structure including the word line WL0 and the cross-sectional structure including the select gate line SGS. That is, the plurality of memory cell transistors MC1 to MC3 and the plurality of selection transistors ST2 allocated to the NAND strings NS0 and NS6 are included in the layer L0. The plurality of memory cell transistors MC1 to MC3 and the plurality of selection transistors ST2 allocated to the NAND strings NS1 and NS7 are included in the layer L1. The plurality of memory cell transistors MC1 to MC3 and the plurality of selection transistors ST2 allocated to the NAND strings NS2 and NS8 are included in the layer L2. The plurality of memory cell transistors MC1 to MC3 and the plurality of selection transistors ST2 allocated to the NAND strings NS3 and NS9 are included in the layer L3. The plurality of memory cell transistors MC1 to MC3 and the plurality of selection transistors ST2 allocated to the NAND strings NS4 and NS10 are included in the layer L4. The plurality of memory cell transistors MC1 to MC3 and the plurality of selection transistors ST2 allocated to the NAND strings NS5 and NS11 are included in the layer L5.

As shown in FIG. 7, the cross-sectional structure including the select gate lines SGD0 and SGD1 and along the X direction includes the conductive layer 38 with a different shape than the cross-sectional structure including the word line WL0 and along the X direction.

Specifically, the conductive layer 38 is separated for each memory cell unit MCP in the cross section including the select gate lines SGD0 and SGD1 and along the X direction. In other words, the conductive layer 38 is provided independently for each string unit SU in the cross section along the X direction including the plurality of select gate lines SGD.

Other structures of the cross section including the select gate lines SGD0 and SGD1 and along the X direction are similar to the structures of the cross section including the word line WL0 and along the X direction. That is, the plurality of selection transistors ST1 allocated to the NAND strings NS0 and NS6 are included in the layer L0. The plurality of selection transistors ST1 allocated to the NAND strings NS1 and NS7 are included in the layer L1. The plurality of selection transistors ST1 allocated to the NAND strings NS2 and NS8 are included in the layer L2. The plurality of selection transistors ST1 allocated to the NAND strings NS3 and NS9 are included in the layer L3. The plurality of selection transistors ST1 allocated to the NAND strings NS4 and NS10 are included in the layer L4. The plurality of selection transistors ST1 allocated to the NAND strings NS5 and NS11 are included in the layer L5.

In addition, as illustrated in FIGS. 6 and 7, the cross-sectional shape of the stacked body 34 along the X direction has a tapered shape. As described above, in the memory device 100, the cross-sectional shape of the stacked body 34 along the X direction can change based on processing characteristics of dry etching or the like in the process of forming the stacked body 34. For this reason, the cross-sectional shape of the stacked body 34 along the X direction may be a reverse tapered shape, a bowing shape, or the like.

In the present example, the width of each of the semiconductor layers 33-0 to 33-5 in the X direction included in the stacked body 34 and the length of the side face of each of the semiconductor layers 33-0 to 33-5 included in the stacked body 34 along the Z direction are different for each layer. As a result, the gate widths of the memory cell transistors MC included in the NAND strings NS0 to NS5 are different for each layer.

Specifically, the gate width of the memory cell transistor MC provided in the layer L0, that is, the length of the word line WL adjacent to the memory cell transistor MC and in the Z direction is shorter than the gate width of the memory cell transistor MC provided in the layer L1. The gate width of the memory cell transistor MC provided in the layer L1 is shorter than the gate width of the memory cell transistor MC provided in the layer L2. The gate width of the memory cell transistor MC provided in the layer L2 is shorter than the gate width of the memory cell transistor MC provided in the layer L3. The gate width of the memory cell transistor MC provided in the layer L3 is shorter than the gate width of the memory cell transistor MC provided in the layer L4. Further, the gate width of the memory cell transistor MC provided in the layer L4 is shorter than the gate width of the memory cell transistor MC provided in the layer L5. That is, in the present example, the gate width of the memory cell transistor MC is longer as the distance from the semiconductor substrate 30 increases.

In addition, the length (width) of the semiconductor layer 33-0 provided in the layer L0 in the X direction is longer than the length of the semiconductor layer 33-1 provided in the layer L1 in the X direction. The length of the semiconductor layer 33-1 provided in the layer L1 in the X direction is longer than the length of the semiconductor layer 33-2 provided in the layer L2 in the X direction. The length of the semiconductor layer 33-2 provided in the layer L2 in the X direction is longer than the length of the semiconductor layer 33-3 provided in the layer L3 in the X direction. The length of the semiconductor layer 33-3 provided in the layer L3 in the X direction is longer than the length of the semiconductor layer 33-4 provided in the layer L4 in the X direction. Further, the length of the semiconductor layer 33-4 provided in the layer L4 in the X direction is longer than the length of the semiconductor layer 33-5 provided in the layer L5 in the X direction. That is, in the present example, the length in the X direction of the semiconductor layer 33 used as part of the memory cell transistor MC is shorter as the distance from the semiconductor substrate 30 increases.

As shown in FIG. 8, the memory device 100 further includes a conductive member 40 and a conductive layer 41. The conductive member 40 has a columnar shape extending along the Z direction, for example, and is used as the contact plug SC. The conductive member 40 penetrates the block insulating film 37, the charge storage layer 36, the tunnel insulating film 35, the insulator layers 32-6 to 32-1, and the semiconductor layers 33-5 and 33-1 in the vicinity of an end of the memory cell unit MCP, that is, the end being away from the bit line coupling portion BLCP. The bottom portion of the conductive member 40 reaches the semiconductor layer 33-0. Thus, the conductive member 40 is electrically coupled to the semiconductor layers 33-0 to 33-5. The conductive member 40 contains, for example, tungsten (W).

The conductive layer 41 is provided on the conductive member 40. The conductive layer 41 has, for example, a portion extending along the X direction, and is used as the source line SL. That is, the conductive layer 41 is electrically coupled to each of the semiconductor layers 33-0 to 33-5 via the conductive member 40 (contact plug SC). The conductive layer 41 contains, for example, copper (Cu).

As illustrated in FIG. 8, the width of the conductive layer 38 separated for each interconnect in the Y direction varies according to the height. As described above, in the memory device 100, the width of the conductive layer 38 separated for each interconnect in the Y direction can be changed based on processing characteristics of dry etching or the like in the process of separating the conductive layer 38 for each interconnect. In the present example, the width of the conductive layer 38 separated for each interconnect in the Y direction is shorter as the distance from the semiconductor substrate 30 increases. In such a case, the gate length of the memory cell transistor MC is different for each NAND string NS.

Specifically, the gate length of the memory cell transistor MC provided in the layer L0 is longer than the gate length of the memory cell transistor MC provided in the layer L1. The gate length of the memory cell transistor MC provided in the layer L1 is longer than the gate length of the memory cell transistor MC provided in the layer L2. The gate length of the memory cell transistor MC provided in the layer L2 is longer than the gate length of the memory cell transistor MC provided in the layer L3. The gate length of the memory cell transistor MC provided in the layer L3 is longer than the gate length of the memory cell transistor MC provided in the layer L4. Further, the gate length of the memory cell transistor MC provided in the layer L4 is longer than the gate length of the memory cell transistor MC provided in the layer L5. That is, in the present example, the gate length of the memory cell transistor MC is shorter as the distance from the semiconductor substrate 30 increases.

As shown in FIG. 9, the memory device 100 further includes a plurality of conductive members 42, a plurality of conductive layers 43, and a plurality of insulator layers 39.

Each conductive member 42 has a columnar shape extending in the Z direction, for example, and is used as a contact plug BC. Specifically, in the bit line coupling portion BLCP of the memory unit MU0, six conductive members 42 (contact plugs BC0 to BC5) are provided on the semiconductor layers 33-0 to 33-5, respectively. In the bit line coupling portion BLCP of the memory unit MU1, six conductive members 42 (contact plugs BC6 to BC11) are provided with on the semiconductor layers 33-0 to 33-5, respectively. In addition, each conductive member 42 penetrates the block insulating film 37, the charge storage layer 36, and the tunnel insulating film 35.

The conductive member 42 coupled to the semiconductor layer 33-0 included in the layer L0 further penetrates the semiconductor layers 33-1 to 33-5 included in the layers L1 to L5. The conductive member 42 coupled to the semiconductor layer 33-0 and each of the semiconductor layers 33-1 to 33-5 are separated and insulated by the insulator layer 39.

The conductive member 42 coupled to the semiconductor layer 33-1 included in the layer L1 further penetrates the semiconductor layers 33-2 to 33-5 included in the layers L2 to L5. The conductive member 42 coupled to the semiconductor layer 33-1 and each of the semiconductor layers 33-2 to 33-5 are separated and insulated by the insulator layer 39.

The conductive member 42 coupled to the semiconductor layer 33-2 included in the layer L2 further penetrates the semiconductor layers 33-3 to 33-5 included in the layers L3 to L5. The conductive member 42 coupled to the semiconductor layer 33-2 and each of the semiconductor layers 33-3 to 33-5 are separated and insulated by the insulator layer 39.

The conductive member 42 coupled to the semiconductor layer 33-3 included in the layer L3 further penetrates the semiconductor layers 33-4 and 33-5 included in the layers L4 and L5. The conductive member 42 coupled to the semiconductor layer 33-3 and each of the semiconductor layers 33-4 and 33-5 are separated and insulated by the insulator layer 39.

The conductive member 42 coupled to the semiconductor layer 33-4 included in the layer L4 further penetrates the semiconductor layer 33-5 included in the layer L5. The conductive member 42 coupled to the semiconductor layer 33-4 and the semiconductor layer 33-5 are separated and insulated by the insulator layer 39. The insulator layer 39 includes, for example, silicon oxide (SiO).

A plurality of conductive layers 43 is provided on the plurality of conductive members 42. The conductive layer 43 has, for example, a portion extending in the Y direction, and is used as the bit line BL. Specifically, the conductive layer 43 provided on the conductive member 42 corresponding to the contact plug BC0 is used as the bit line BL0. The conductive layer 43 provided on the conductive member 42 corresponding to the contact plug BC1 is used as the bit line BL1. The conductive layer 43 provided on the conductive member 42 corresponding to the contact plug BC2 is used as the bit line BL2. Similarly, each conductive layer 43 is used as the bit line BL associated with the semiconductor layer 33 coupled via the contact plug BC. The conductive layer 43 contains, for example, copper (Cu).

### 1.4 Configuration of Sense Amplifier Module and Data Register

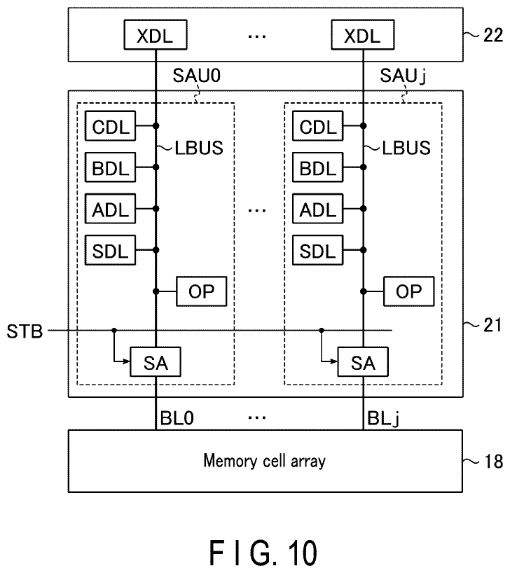

Next, an example of a configuration of the sense amplifier module 21 and the data register 22 will be described with reference to FIG. 10. FIG. 10 is a block diagram illustrating an example of a configuration of the sense amplifier module 21 and the data register 22.

As illustrated in FIG. 10, the sense amplifier module 21 includes a plurality of sense amplifier units SAU provided for each bit line BL. In the example illustrated in FIG. 10, the sense amplifier module 21 includes sense amplifier units SAU0 to SAUj (j is an integer of one or more). The sense amplifier units SAU0 to SAUj are coupled to the bit lines BL0 to BLj, respectively. The data register 22 includes, for example, a plurality of latch circuits XDL provided for each sense amplifier unit SAU.

For example, the sense amplifier unit SAU includes a sense circuit SA, an operation unit OP, and latch circuits SDL, ADL, BDL, and CDL. The sense circuit SA, the operation unit OP, and the latch circuits SDL, ADL, BDL, and CDL are commonly coupled to the corresponding latch circuit XDL via a bus LBUS. In other words, the latch circuit XDL, the sense circuit SA, the operation unit OP, and the latch circuits SDL, ADL, BDL, CDL, and XDL are coupled so as to be able to transmit and receive data to and from each other via the bus LBUS. The number of latch circuits included in the sense amplifier unit SAU can be designed based on the number of bits of data that can be stored in one memory cell transistor MC.

The sense circuit SA reads the data of the memory cell transistor MC at the time of the read operation. More specifically, at the time of the read operation, the sense circuit SA senses the data read to the bit line BL corresponding to the selected memory cell transistor MC, and determines whether the read data is “0” or “1”. In addition, the sense circuit SA applies a voltage to the bit line BL based on the write data at the time of the write operation.

A control signal STB is input to each sense circuit SA. In a case where the control signal STB is asserted at the time of the read operation, the sense circuit SA determines whether the read data of the selected memory cell transistor MC is “0” or “1” based on the voltage or the current of the associated bit line BL. Hereinafter, the determination operation based on the control signal STB is referred to as a “strobe operation”.

The operation unit OP performs various logical operations using data stored in the sense circuit SA and the latch circuits XDL, SDL, ADL, BDL, and CDL.

The latch circuits SDL, ADL, BDL, CDL, and XDL temporarily store data. For example, at the time of the read operation, the read data determined by the sense circuit SA is transferred to any of the latch circuits SDL, ADL, BDL, CDL, and XDL via the operation unit OP. For example, at the time of the write operation, the write data transferred from the input/output circuit 10 to the latch circuit XDL is transferred to any of the latch circuits SDL, ADL, BDL, and CDL.

### 1.4.1 Circuit Configuration of Sense Amplifier Unit SAU

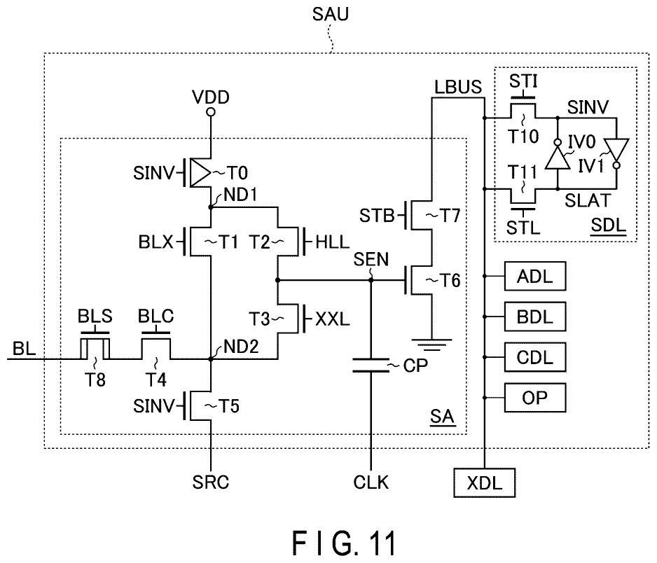

Next, an example of a circuit configuration of the sense amplifier unit SAU will be described with reference to FIG. 11. FIG. 11 is a circuit diagram illustrating an example of a circuit configuration of the sense amplifier unit SAU. Note that, in the example illustrated in FIG. 11, in order to simplify the description, the circuit configurations of the latch circuits ADL, BDL, and CDL and the operation unit OP are omitted.

As illustrated in FIG. 11, the sense circuit SA includes transistors T0 to T8 and a capacitance element CP. The latch circuit SDL includes inverters IV0 and IV1 and transistors T10 and T11. The transistor T0 is a P-type metal-oxide-semiconductor (MOS) transistor. Each of the transistors T1 to T7, T10, and T11 is an N-type MOS transistor. The transistor T8 is an N-type MOS transistor having a higher withstand voltage than each of the transistors T0 to T7.

The source of the transistor T0 is coupled to the power supply line. The drain of the transistor T0 is coupled to a node ND1. The gate of the transistor T0 is coupled to a node SINV in the latch circuit SDL.

The drain of the transistor T1 is coupled to the node ND1. The source of the transistor T1 is coupled to a node ND2. A control signal BLX is input to the gate of the transistor T1.

The drain of the transistor T2 is coupled to the node ND1. The source of the transistor T2 is coupled to a node SEN. A control signal HLL is input to the gate of the transistor T2.

The drain of the transistor T3 is coupled to the node SEN. The source of the transistor T3 is coupled to the node ND2. A control signal XXL is input to the gate of the transistor T3.

The drain of the transistor T4 is coupled to the node ND2. A control signal BLC is input to the gate of the transistor T4.

The drain of the transistor T5 is coupled to the node ND2. The source of the transistor T5 is coupled to a node SRC. The gate of the transistor T5 is coupled to, for example, the node SINV in the latch circuit SDL.

The source of the transistor T6 is grounded. The gate of the transistor T6 is coupled to the node SEN.

The drain of the transistor T7 is coupled to the bus LBUS. The source of the transistor T7 is coupled to the drain of the transistor T6. The control signal STB is input to the gate of the transistor T7.

One electrode of the capacitance element CP is coupled to the node SEN. A clock signal CLK is input to the other electrode of the capacitance element CP.

The drain of the transistor T8 is coupled to the source of the transistor T4. The source of the transistor T8 is coupled to the associated bit line BL. A control signal BLS is input to the gate of the transistor T8.

The input node of the inverter IV0 is coupled to a node SLAT. The output node of the inverter IV0 is coupled to the node SINV.

The input node of the inverter IV1 is coupled to the node SINV. The output node of the inverter IV1 is coupled to the node SLAT.

One end of a current path of the transistor T10 is coupled to the node SINV. The other end of the current path of the transistor T10 is coupled to the bus LBUS. A control signal ST1 is input to the gate of the transistor T10.

One end of a current path of the transistor T11 is coupled to the node SLAT. The other end of the current path of the transistor T11 is coupled to the bus LBUS. A control signal STL is input to the gate of the transistor T11.

For example, the data stored in the node SLAT corresponds to the data stored in the latch circuit SDL. On the other hand, the data stored in the node SINV corresponds to inverted data of the data stored in the node SLAT.

The circuit configuration of each of the latch circuits ADL, BDL, and CDL are similar to, for example, that of the latch circuit SDL.

In the circuit configuration of the sense amplifier unit SAU described above, for example, a power supply voltage VDD is applied to the power supply line coupled to the source of the transistor T0. For example, a ground voltage VSS is applied to the node SRC. Each of the control signals BLX, HLL, XXL, BLC, STB, BLS, STI, and STL and the clock signal CLK is generated by, for example, the sequencer 15. The node SEN may be referred to as a sense node of the sense circuit SA.

The sense circuit SA determines the data read to the bit line BL based on the timing at which the control signal STB is asserted at the “H” level.

Next, the operation of the sense circuit SA at the time of the read operation will be briefly described. At the time of reading, first, the node SINV is set to the “L” level, and the transistor T0 is turned on. Furthermore, in a case where the transistors T1 and T8 are turned on and a signal BLC (clamp voltage) is applied to the transistor T4, the bit line BL is precharged (charged) to a voltage corresponding to the signal BLC via the transistors T0, T1, T4, and T8. In a case where the transistor T2 is turned on, the node SEN is precharged to a voltage VDD.

After the transistor T2 is turned off, the transistor T3 is turned on. In a case where the threshold voltage of the memory cell transistor MC (hereinafter, referred to as a “selected memory cell transistor MC”) to be read is lower than the read voltage, the selected memory cell transistor MC is turned on (hereinafter, referred to as an “ON-cell”). In this case, since the current flows from the bit line BL to the source line SL, the potential of the node SEN decreases. In a case where the potential of the node SEN is lower than the threshold voltage of the transistor T6, the transistor T6 is turned off. On the other hand, in a case where the threshold voltage of the selected memory cell transistor MC is equal to or higher than the read voltage, the selected memory cell transistor MC is turned off (hereinafter, referred to as an “Off-cell”). In this case, since almost no current flows from the bit line BL to the source line SL, the potential of the node SEN is almost maintained. As a result, the transistor T6 is turned on.

Next, the strobe operation is executed. In a case where the control signal STB is set to the “H” level and the transistor T7 is turned on, a potential according to the determination of on/off of the transistor T6 is read to the bus LBUS. In a case where the transistor T6 is turned off, that is, in a case of the ON-cell, the bus LBUS is set to the “H” level by the strobe operation. In a case where the transistor T6 is turned on, that is, in a case of the Off-cell, the bus LBUS is set to the “L” level by the strobe operation. In a case where the bus LBUS is at the “H” level, for example, “1” data is stored in the latch circuit SDL. On the other hand, in a case where the bus LBUS is at the “L” level, for example, “0” data is stored in the latch circuit SDL. That is, in the case of the ON-cell, “1” data is stored in the latch circuit SDL. In the case of the Off-cell, “0” data is stored in the latch circuit SDL.

In a case where the latch circuit SDL stores “1” data, the node SINV is at the “L” level. On the other hand, in a case where the latch circuit SDL stores “0” data, the node SINV is at the “H” level.

### 1.5 Threshold Voltage Distribution of Memory Cell Transistor

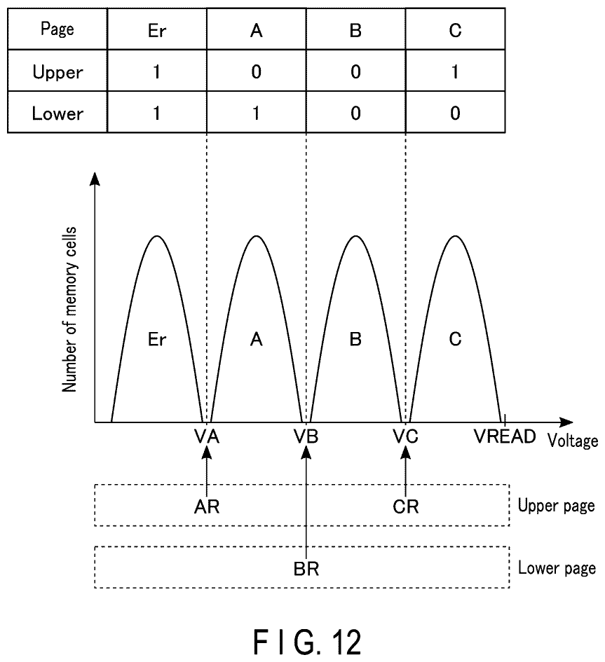

Next, an example of the threshold voltage distribution of the memory cell transistor MC will be described with reference to FIG. 12. FIG. 12 is a diagram illustrating a threshold voltage distribution and data allocation in a case where the memory cell transistor MC is an MLC capable of storing 2-bit data.

As illustrated in FIG. 12, in a case where the memory cell transistor MC stores 2-bit data, the distribution of the threshold voltage is divided into 4 (2²). These four threshold voltage distributions (threshold voltage ranges) are referred to as an Er state, an A state, a B state, and a C state in ascending order of the threshold voltage. Note that the number of threshold voltage distributions can be represented by 2ⁿ (n is the number of bits of the memory cell transistor MC).

The voltages VA to VC are verification voltages used for the program verification operation of each of the A state to the C state at the time of the write operation. The voltages VA to VC are voltages applied to the selected word line WL at the time of the program verification operation. The voltage VREAD is a voltage applied to the non-selected word line WL at the time of the read operation (and at the time of the program verification operation). In a case where the voltage VREAD is applied to the gate of the memory cell transistor MC, the memory cell transistor MC is turned on regardless of stored data. The relationship between the voltages VA to VC and the voltage VREAD is VA<VB<VC<VREAD.

The Er state corresponds to an erase state of the memory cell transistor MC. Each of the A state to the C state corresponds to a state in which charges are injected into the charge storage layer 36 of the memory cell transistor MC and data is written. The threshold voltage of the memory cell transistor MC included in the Er state is less than the voltage VA. The threshold voltage of the memory cell transistor MC included in the A state is equal to or more than the voltage VA and less than the voltage VB. The threshold voltage of the memory cell transistor MC included in the B state is equal to or more than the voltage VB and less than the voltage VC. The threshold voltage of the memory cell transistor MC included in the C state is equal to or more than the voltage VC and less than the voltage VREAD.

The set value of the verification voltage and the set value of the read voltage corresponding to each state may be the same or different.

Hereinafter, the read operation using the voltages VA to VC will be referred to as read operations AR to CR, respectively. The read operation AR determines whether the threshold voltage of the memory cell transistor MC is less than the voltage VA. The read operation BR determines whether the threshold voltage of the memory cell transistor MC is less than the voltage VB. The read operation CR determines whether the threshold voltage of the memory cell transistor MC is less than the voltage VC.

As described above, the threshold voltage of each memory cell transistor MC belongs to any of the four threshold voltage distributions. As a result, each of the memory cell transistors MC can take four types of states. By allocating these states to the data “00” to “11” in binary numeral, each memory cell transistor MC can store 2-bit data. Hereinafter, the 2-bit data is referred to as a “Lower bit” and an “Upper bit” in order from the lower bit. A set of Lower bits stored in the memory cell transistors MC included in the same cell unit CU is referred to as “Lower page data”, and a set of Upper bits is referred to as “Upper page data”.

In the example illustrated in FIG. 12, data of “Upper bit/Lower bit” is allocated to the memory cell transistor MC included in each state as shown below.

Er state: “11” data

A state: “01” data

B state: “00” data

C state: “10” data

In the case of reading the data allocated in this manner, the Lower bit is determined by the read operation BR. The Upper bit is determined by the read operations AR and CR.

### 1.6 Write Operation

Next, the write operation will be described. The write operation includes a program operation and a program verification operation. The sequencer 15 increases the threshold voltage of the memory cell transistor MC to the target level by repeating a combination (hereinafter, referred to as a “program loop”) of the program operation and the program verification operation. In a case where the program loop is repeated, the program voltage applied to the selected word line WL is stepped up.

The program operation is an operation of injecting electrons into the charge storage layer 36 or prohibiting injection of electrons into the charge storage layer 36 of the selected memory cell transistor MC as a target of the write operation based on the write data. In a case where electrons are injected into the charge storage layer 36, the threshold voltage of the selected memory cell transistor MC increases. In other words, the program operation is an operation of increasing the threshold voltage of the selected memory cell transistor MC or maintaining the threshold voltage based on the write data. Hereinafter, among the selected memory cell transistors MC, the memory cell transistor MC that increases the threshold voltage is referred to as a “memory cell transistor MC to be programmed”. Among the selected memory cell transistors MC, the memory cell transistor MC that does not raise the threshold voltage is referred to as a “program inhibited memory cell transistor MC”.

The program verification operation is an operation of reading data from the selected memory cell transistor MC after the program operation and determining whether the threshold voltage of the selected memory cell transistor MC has reached a target level (state). For example, in a case where the selected memory cell transistor MC is an Off-cell in the program verification operation, the threshold voltage of the memory cell transistor MC has reached the target level. On the other hand, in a case where the selected memory cell transistor MC is an ON-cell, the threshold voltage of the memory cell transistor MC does not reach the target level. For example, in the case of the Off-cell, the node SEN is set to the “H” level, that is, the “1” data is stored in the sense circuit SA. Furthermore, for example, in the case of the ON-cell, the node SEN is set to the “L” level. That is, “O” data is stored in the sense circuit SA.

Hereinafter, a case where the threshold voltage of the memory cell transistor MC has reached the target level is referred to as “verification passed”, and a case where the threshold voltage has not reached the target level is referred to as “verification failed”. In a case where the number of fail bits of the read data is equal to or greater than a preset reference value, it is determined that “verification failed”. In a case where the verification failed, the threshold voltage of the memory cell transistor MC is increased to the target level by repeating the program loop. The memory cell transistor MC to be programmed in which the threshold voltage has reached the target level is program inhibited in the subsequent program loop. That is, the memory cell transistor MC that has completed the program is program inhibited.

### 1.6.1 Setting of Verification Voltage at Time of Program Verification Operation

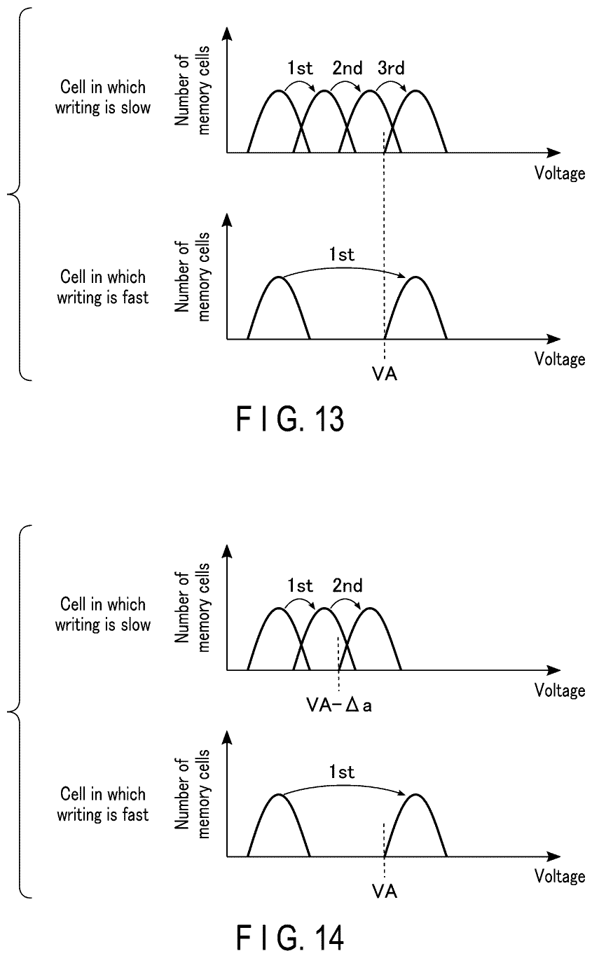

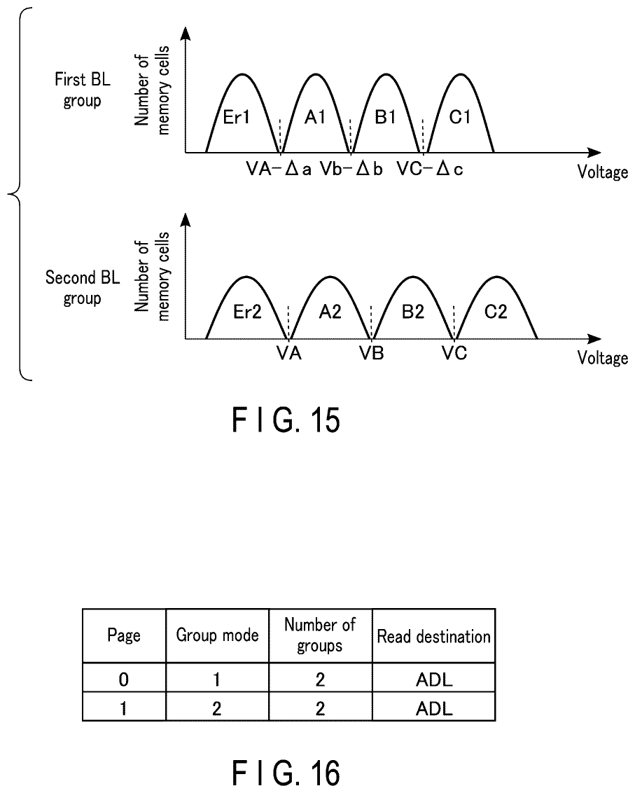

Next, the setting of the verification voltage at the time of the program verification operation will be described with reference to FIGS. 13 to 15. FIG. 13 is a diagram illustrating a relationship between the verification voltage of the A state and the number of program loops in the comparative embodiment. FIG. 14 is a diagram illustrating a relationship between the verification voltage of the A state and the number of program loops in the embodiment. FIG. 15 is a diagram illustrating a relationship between a threshold voltage distribution and a verification voltage for each BL group in a case where the memory cell transistor MC is an MLC.

For example, as described with reference to FIGS. 7 and 8, the size (gate length, gate width, and the like) of the memory cell transistor MC of each layer L differs depending on the processing characteristics of the stacked body 34 and the conductive layer 38 (word line WL). Therefore, even in a case where the same program condition is applied, the increase amount of the threshold voltage by one program operation varies depending on the layer L. Hereinafter, the memory cell transistor MC in which the increase amount of the threshold voltage by one program operation is relatively large is referred to as a “memory cell transistor MC in which writing is fast”. On the other hand, the memory cell transistor MC in which the increase amount of the threshold voltage by one program operation is relatively small is referred to as a “memory cell transistor MC in which writing is slow”.

As shown in FIG. 13, in the comparative embodiment, the same verification voltage VA is set for the memory cell transistors MC having different write speeds (layers L).

For example, in the memory cell transistor MC in which writing is fast, writing of the A state is completed by one program operation. On the other hand, in the memory cell transistor MC in which writing is slow, writing is completed by three program operations. Therefore, three program loops are required to complete the writing of the A state to all the memory cell transistors MC to be programmed.

As shown in FIG. 14, in the embodiment, different verification conditions are set for the memory cell transistors MC having different write speeds (layers L). In the example illustrated in FIG. 14, the voltage VA is set as the verification voltage of the memory cell transistor MC in which the write operation is fast. On the other hand, a voltage VA−Δa obtained by subtracting the shift value Δa from the voltage VA is set as the verification voltage of the memory cell transistor MC in which the write operation is slow. The voltage VA and the voltage VA−Δa have a relationship of VA>VA−Δa. As a result, for example, in the memory cell transistor MC in which writing is slow, the writing is ended by two program operations. Therefore, writing of the A state to all the memory cell transistors MC to be programmed can be completed in two program loops.

As illustrated in FIG. 15, in the present embodiment, the bit lines BL are grouped based on the corresponding layer L. Then, a different verification condition is set for each group (hereinafter, referred to as a “BL group”) of the bit lines BL. For example, the first BL group includes the memory cell transistor MC in which writing is slow, and the second BL group includes the memory cell transistor MC in which writing is fast. In this case, the voltages VA, VB, and VC are set as verification voltages corresponding to the second BL group, that is, the A to C states of the memory cell transistor MC in which writing is fast. In addition, voltages VA−Δa, VB−Δb, and VC−Δc are set as verification voltages corresponding to the first BL group, that is, the A to C states of the memory cell transistor MC in which writing is slow. The voltages VA−Δa, VA, VB−Δb, VB, VC−Δc, and VC have a relationship of (VA−Δa)<VA<(VB−Δb)<VB<(VC−Δc)<VC.

(The width of) the threshold voltage distribution corresponding to the first BL group is different from (the width of) the threshold voltage distribution corresponding to the second BL group. Hereinafter, in a case where the Er, A, B, and C states are distinguished for each BL group, the Er, A, B, and C states corresponding to the first BL group are referred to as Er1, A1, B1, and C1 states. In addition, the Er, A, B, and C states corresponding to the second BL group are referred to as Er2, A2, B2, and C2 states.

The shift values Δa, Δb, and Δc with respect to the verification voltages VA, VB, and VC can be set arbitrary. For example, the memory controller 200 may have a table for managing the shift values Δa, Δb, and Δc.

In the present example, the case where there are two BL groups is described, but three or more BL groups may be provided. In addition, the first BL group may include the memory cell transistor MC in which writing is fast, and the second BL group may include the memory cell transistor MC in which writing is slow.

### 1.6.2 Specific Examples of Group Mode Table and BL Group

Next, an example of a group mode table 221 will be described with reference to FIG. 16. FIG. 16 is a table illustrating an example of the group mode table 221.

As illustrated in FIG. 16, the group mode table 221 is a table indicating in which page address in the user ROM area 120 the group information (hereinafter, it is referred to as “bit-by-bit group information”) of each bit at the time of setting the group mode is registered. The group data is data indicating bit-by-bit group information. The memory cell transistor MC in the user ROM area 120 is an SLC. Therefore, the page number corresponds to any cell unit CU in the user ROM area 120.

The group mode table 221 includes a plurality of entries. Each entry includes a page number (page address) of the group data, a group mode, the number of groups of the BL group, and information about the latch circuit of group data read destination.

In the write operation in which the group mode (that is, a plurality of BL groups) is set, the read operation of the group data (referred to as “group data read”) is executed before the first program operation is executed. The group data read by the group data read is stored in a latch circuit of the read destination of each sense amplifier unit SAU. At the time of the program verification operation, the operation with the write data and the group data stored in the latch circuit are executed. As a result, verification determination can be performed under different verification conditions for each BL group.

Each entry indicates in which page address of the user ROM area 120 the group data used in the program verification operation is registered. The page number corresponds to any cell unit CU in the user ROM area 120.

For example, group mode 1 is allocated to page 0 of the user ROM area 120. For example, group mode 2 is allocated to page 1 of the user ROM area 120. The group mode indicates a grouping pattern of BL groups. For example, the mode 1 and the mode 2 show a case where the bit line BL (layer L) is divided into two groups. The grouping of the bit line BL (layer L) is different between the mode 1 and the mode 2. For example, in the mode 1, the bit lines BL corresponding to the layers L0 to L2 belong to the first BL group, and the bit lines BL corresponding to the layers L3 to L5 belong to the second BL group. On the other hand, for example, in the mode 2, the bit lines BL corresponding to the layers L0 and L1 belong to the first BL group, and the bit lines BL corresponding to the layers L2 to L5 belong to the second BL group.

The number of groups indicates the number of BL groups in the corresponding group mode. For example, the number of groups of the modes 1 and 2 is two. Therefore, the BL group to which each bit line BL belongs can be represented by 1-bit data. For example, the “0” data indicates the first BL group. The “1” data indicates the second BL group. That is, the group data of each of the modes 1 and 2 is one page data. Note that the number of groups is not limited to two. The number of groups may be three or more. In this case, the group data corresponding to the mode may be two page data or more.

For example, the read destinations of page 0 and page 1 in the user ROM area 120 are the latch circuit ADL.

### 1.6.3 Flow of Write Operation

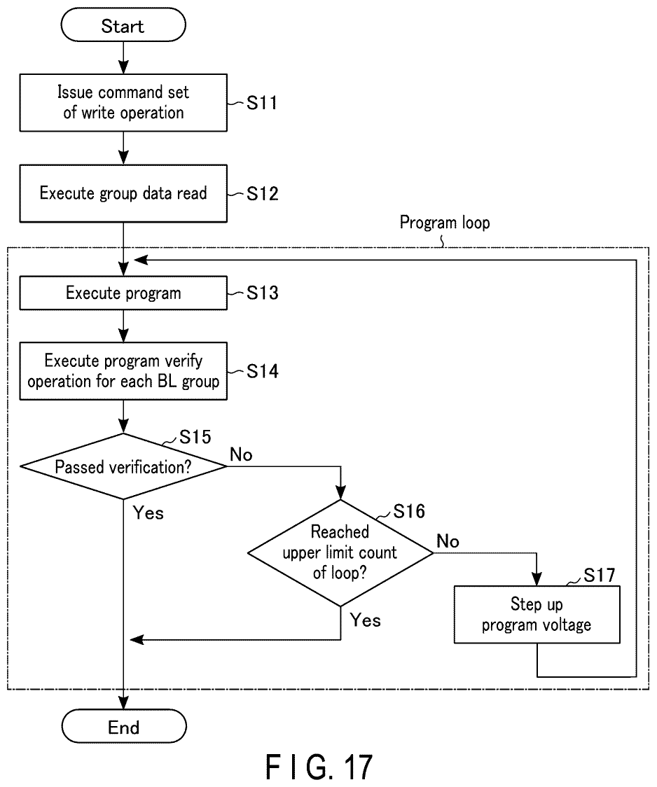

Next, a flow of the write operation will be described with reference to FIG. 17. FIG. 17 is a flowchart illustrating a flow of the write operation. Hereinafter, the word line WL coupled to the memory cell transistor MC (cell unit CU) to be written is referred to as a “selected word line WL”. Each of the other word lines WL is referred to as a “non-selected word line WL”.

As illustrated in FIG. 17, upon receiving a write request from the host 2, the CPU 230 refers to the group mode table 221 and issues a command set of the write operation (S11). The command set of the present embodiment includes a command of the group data read, an address of the group data, a command of the write operation, an address of the write destination of the write data, and the write data. The address of the group data indicates the user ROM area 120. The address of the write destination indicates the user data area 110. A command sequence of the write operation will be described later. The CPU 230 transmits the issued command set to the memory device 100.

Upon receiving the command set, the sequencer 15 first executes the group data read (S12). More specifically, the sequencer 15 reads the group data of the target page in the user ROM area 120 to store the data in the latch circuit (for example, the latch circuit ADL) of the read destination.

Next, the sequencer 15 starts a program loop. More specifically, the sequencer 15 first executes a program operation (S13). At this time, a program voltage is applied to the selected word line WL.

After completion of the program operation, the sequencer 15 executes the program verification operation to which different verification conditions are applied for each BL group (S14).

In a case where the verification failed (S15_No), the sequencer 15 checks whether the number of program loops has reached the upper limit number.

In a case where the number of program loops has not reached the upper limit number (S16_No), the sequencer 15 steps up the setting of the program voltage (S17). Next, the sequencer 15 advances the process to step S13 and repeats the program loop.

In a case where the verification was passed (S15_Yes) or in a case where the number of program loops has reached the upper limit number of times (S16_Yes), the sequencer 15 ends the write operation.

### 1.6.4 Command Sequence of Write Operation

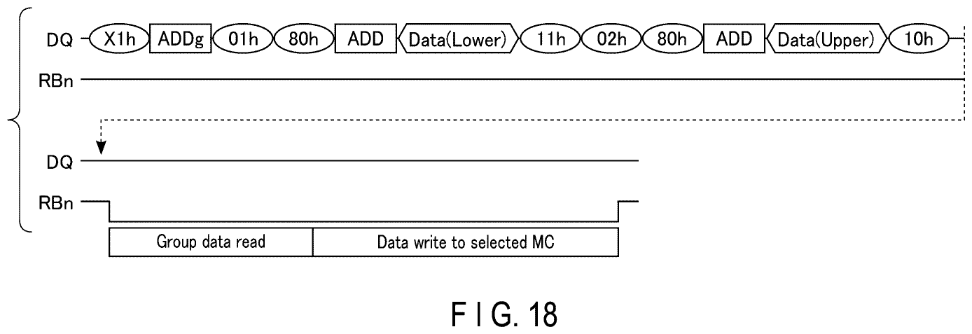

Next, an example of a command sequence of the write operation will be described with reference to FIG. 18. FIG. 18 is a diagram illustrating an example of a command sequence of the write operation. In the diagram of the command sequence described below, a round frame indicates a command, a square frame indicates an address, and a hexagonal frame indicates data.

As illustrated in FIG. 18, first, the memory controller 200 transmits a command “X1 h” and an address” ADDg” to the memory device 100. The command “X1 h” is a prefix command indicating access to the user ROM area 120, reading the SLC data, and that the read destination is the latch circuit ADL. The address “ADDg” is an address designating the cell unit CU of the target page of the group data. Note that, for example, in a case where the group data is stored in the RAM 220, the memory controller 200 may transmit the group data instead of the address “ADDg”. In addition, for example, data for setting the shift values Δa, Δb, and Δc of the verification voltage may be transmitted after the address “ADDg”. As a result, for example, the shift of the verification voltage can be set for each group mode.

Next, the memory controller 200 transmits commands “01 h” and “80 h”, an address “ADD”, and Lower page data to the memory device 100. The command “01 h” is a command designating the Lower page. The command “80 h” is a command making a notification of execution of the write operation. The address “ADD” is an address designating the target cell unit CU of the user data area 110. Note that the address “ADD” may include information designating the Lower page. In this case, the command “01 h” may be omitted. The Lower page data is stored in the plurality of latch circuits XDL. Next, the memory controller 200 transmits a command “11 h” to the memory device 100. The command “11 h” is a command making a notification that it is a write operation of a plurality of pages. Upon receiving the command “11 h”, the sequencer 15 transfers the Lower page data (Lower bit) of the latch circuit XDL to, for example, the latch circuit BDL.

Next, the memory controller 200 transmits commands “02 h” and “80 h”, the address “ADD”, and Upper page data to the memory device 100. The command “02 h” is a command designating the Upper page. Note that the address “ADD” may include information designating the Upper page. In this case, the command “02 h” may be omitted. The Upper page data is stored in the plurality of latch circuits XDL.

Next, the memory controller 200 transmits a command “10 h” to the memory device 100. The command “10 h” is a command instructing execution of the write operation. Upon receiving the command “10 h”, the sequencer 15 transfers the Upper page data (Upper bit) of the latch circuit XDL to, for example, the latch circuit CDL. Next, the sequencer 15 sets the ready/busy signal RBn to the “L” level. First, the sequencer 15 executes the group data read. In a case where the group data read ends, the sequencer 15 repeats a program loop to write data in the selected memory cell transistors MC. In a case where the write operation is ended, the sequencer 15 sets the ready/busy signal RBn to the “H” level.

### 1.6.5 Voltage of Selected Word Line at Time of Program Verification Operation

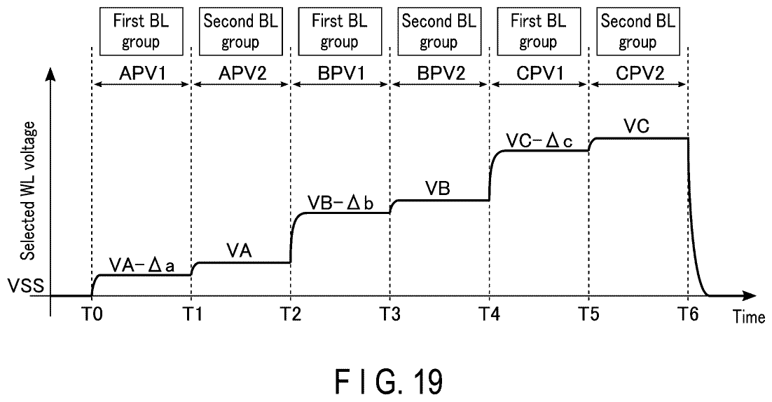

Next, an example of the voltage of the selected word line WL at the time of the program verification operation will be described with reference to FIG. 19. FIG. 19 is a timing chart illustrating an example of the voltage of the selected word line WL in the program verification operation.

As illustrated in FIG. 19, a plurality of verification voltages corresponding to the states and the BL groups are applied to the selected word line WL in ascending order.

During the period from the time T0 to the time T1, first, the verification voltage (VA−Δa) corresponding to the program verification operation APV1 of the A1 state of the first BL group is applied to the selected word line WL.

During the period from the time T1 to the time T2, the verification voltage VA corresponding to the program verification operation APV2 of the A2 state of the second BL group is applied to the selected word line WL.

During the period from the time T2 to the time T3, the verification voltage (VB−Δb) corresponding to the program verification operation BPV1 of the B1 state of the first BL group is applied to the selected word line WL.

During the period from the time T3 to the time T4, the verification voltage VB corresponding to the program verification operation BPV2 of the B2 state of the second BL group is applied to the selected word line WL.

During the period from the time T4 to the time T5, the verification voltage (VC−Δc) corresponding to the program verification operation CPV1 of the C1 state of the first BL group is applied to the selected word line WL.

During the period from time T5 to time T6, the verification voltage VC corresponding to the program verification operation CPV2 of the C2 state of the second BL group is applied to the selected word line WL.

In the example illustrated in FIG. 19, the verification voltages corresponding to the A to C states are applied in one program verification operation, but the present invention is not limited thereto. For example, a state (verification voltage) to be verified may be appropriately selected according to the number of program loops (amount of increase in threshold voltage). For example, A1 and A2 states may be selected as targets in the program verification operation of the first program loop, and B1, B2, C1, and C2 states may be selected as targets in the program verification operation of the fifth program loop.

### 1.6.6 Specific Example of Write Operation

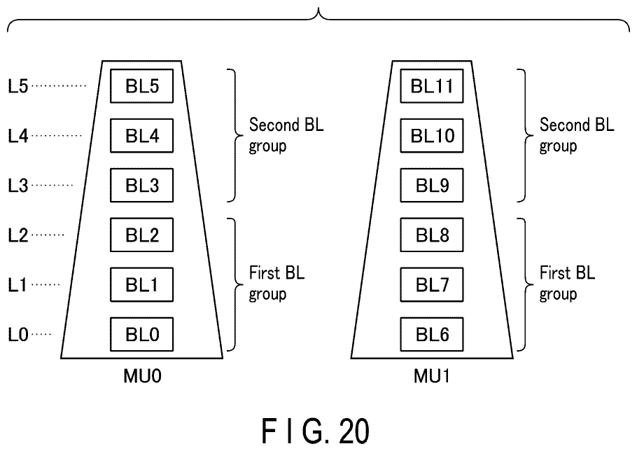

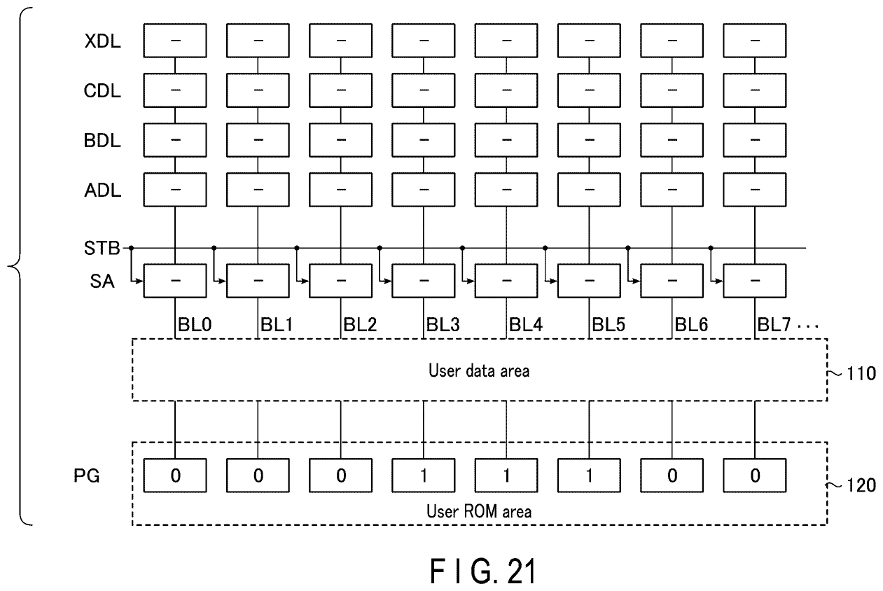

Next, a specific example of the write operation will be described with reference to FIGS. 20 to 33. FIG. 20 is a diagram schematically illustrating an example of grouping of the bit lines BL. FIGS. 21 to 33 are diagrams illustrating an example of states of the latch circuits at the time of the write operation. In the examples illustrated in FIGS. 21 to 33, the operation unit OP and the latch circuit SDL are omitted. In FIGS. 21 to 33, a square frame in the user ROM area 120 corresponds to one memory cell transistor MC (SCL).

In the following arithmetic expressions, “\tilde{ }” represents inverted data, “|” represents an OR operation, and “&” represents an AND operation. Further, 1-bit data stored in the sense circuit SA, the latch circuit ADL, the latch circuit BDL, the latch circuit CDL, and the latch circuit XDL is simply referred to as “SA”, “ADL”, “BDL”, “CDL”, and “XDL”, respectively.

First, the BL group in the specific example will be described.

As shown in FIG. 20, in the specific example, the bit lines BL0 to BL2 and BL6 to BL8 corresponding to the layers L0 to L2 belong to the first BL group, and the bit lines BL3 to BL5 and BL9 to BL11 corresponding to the layers L3 to L5 belong to the second BL group.

Next, the states of the latch circuits at the time of the write operation will be described.

As illustrated in FIG. 21, the group data is stored in the page PG of the user ROM area 120. For example, “0” data indicates a first BL group, and “1” data indicates a second BL group. The bit lines BL0, BL1, BL2, BL6, and BL7 belong to the first BL group, and the bit lines BL3, BL4, and BL5 belong to the second BL group.

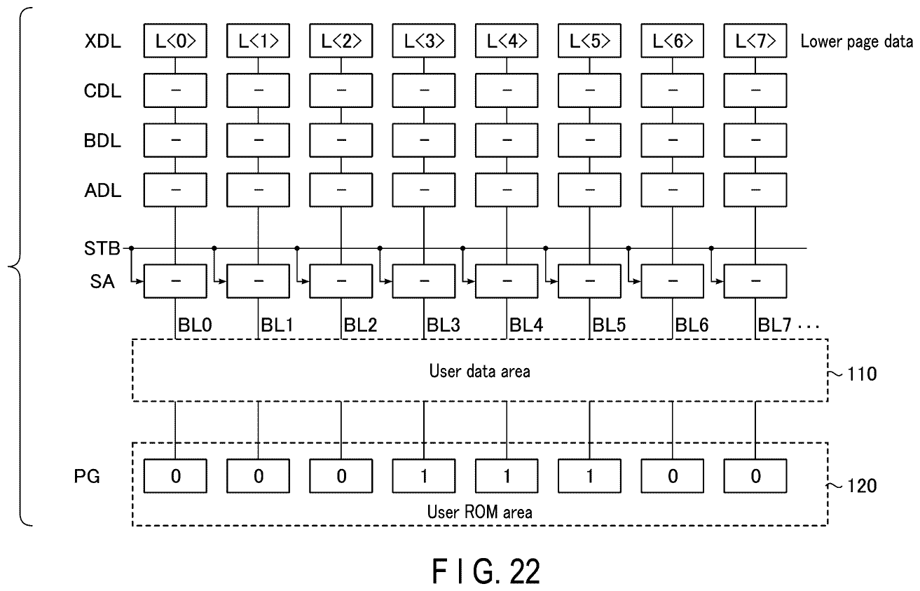

As illustrated in FIG. 22, for example, in a case where the Lower page data is received in the command sequence described with reference to FIG. 18, each bit (Lower bit data) of the Lower page data is stored in the latch circuit XDL. In the example illustrated in FIG. 22, the Lower bit data L<0> to L<7> are stored in the latch circuits XDL corresponding to the bit lines BL0 to BL7, respectively.

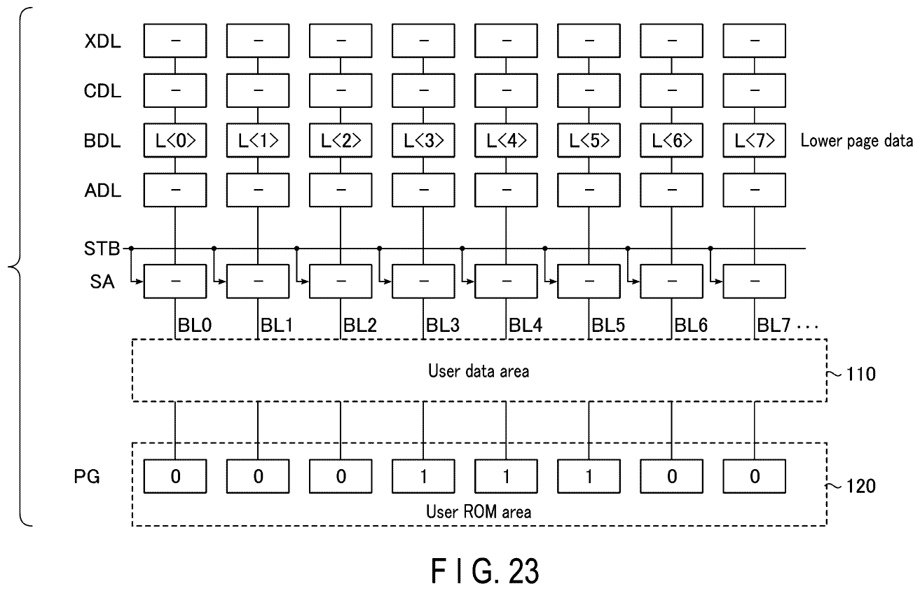

As illustrated in FIG. 23, for example, the data of the latch circuits XDL is transferred to the latch circuits BDL at the timing of receiving the command “11 h” in the command sequence described with reference to FIG. 18. Lower bit data L<0> to L<7> are stored in the latch circuits BDL corresponding to the bit lines BL0 to BL7, respectively. As a result, the latch circuit XDL enters a state in which the latch circuit XDL can receive the next data.

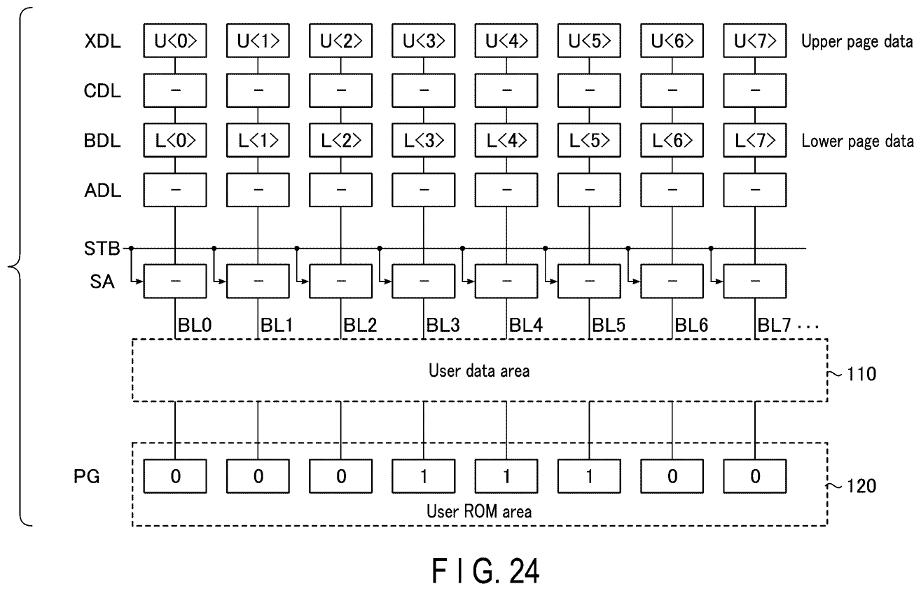

As illustrated in FIG. 24, for example, in a case where the Upper page data is received in the command sequence described with reference to FIG. 18, each bit (upper bit data) of the Upper page data is stored in the latch circuit XDL. In the example illustrated in FIG. 24, the upper bit data U<0> to U<7> are stored in the latch circuits XDL corresponding to the bit lines BL0 to BL7, respectively.

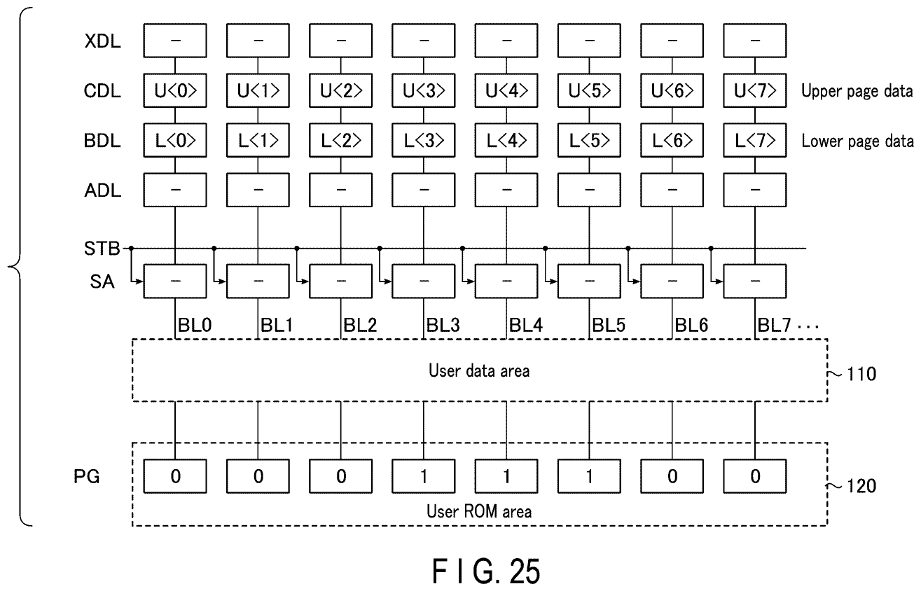

As illustrated in FIG. 25, for example, the data of the latch circuits XDL is transferred to the latch circuits CDL at the timing of receiving the command “10 h” in the command sequence described with reference to FIG. 18. Upper bit data U<0> to U<7> are stored in the latch circuits CDL corresponding to the bit lines BL0 to BL7, respectively.

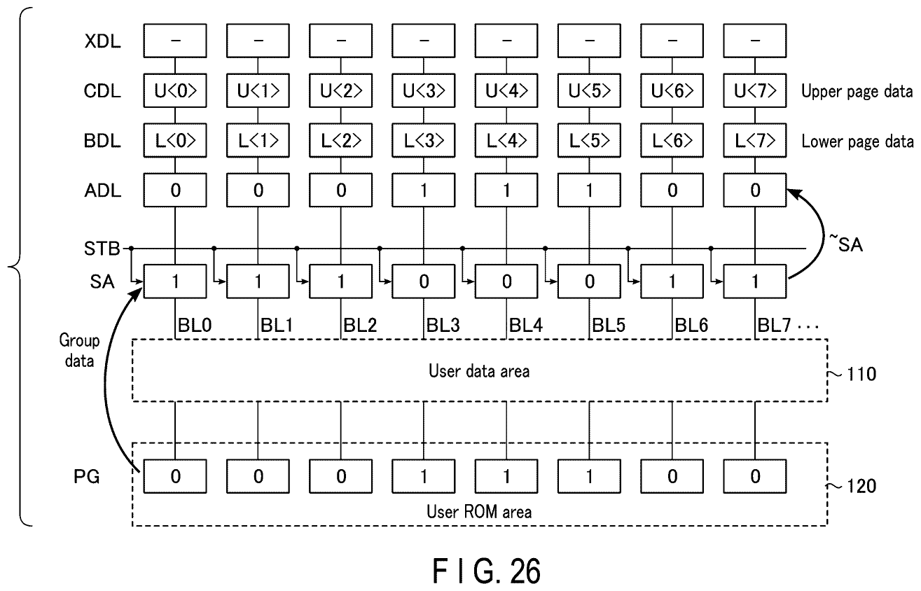

As illustrated in FIG. 26, for example, in the command sequence described with reference to FIG. 18, the sequencer 15 sets the ready/busy signal RBn to the “L” level and then executes the group data read of the page PG. First, the sense circuit SA reads the group data stored in the page PG. At this time, the group data is inverted in the sense circuit SA. The operation unit OP transfers inverted data (~SA) of data stored in the sense circuit SA to the latch circuit ADL. As a result, the same data as the page PG is stored in the latch circuits ADL.

The sequencer 15 executes data writing to the selected memory cell transistors MC after the group read is ended.

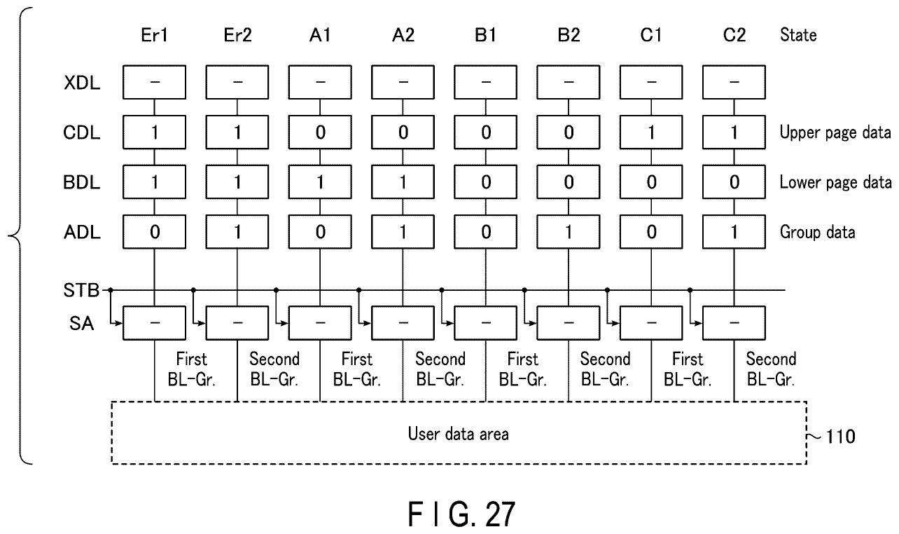

FIGS. 27 to 33 illustrate examples of states of a set of the sense circuit SA and the latch circuits ADL, BDL, CDL, and XDL corresponding to the states Er1, Er2, A1, A2, B1, B2, C1, and C2, respectively. Each sense circuit SA corresponding to the Er1, A1, B1, or C1 state is coupled to the bit line BL of the first BL group (First BL-Gr.). Each sense circuit SA corresponding to the Er2, A2, B2, or C2 state is coupled to the bit line BL of the second BL group (Second BL-Gr.). Data of the Er1, A1, B1, or C1 states is written to the selected memory cell transistors MC corresponding to the bit lines BL of the first BL group. Data of the Er2, A2, B2, or C2 states is written to the selected memory cell transistors MC corresponding to the bit lines BL of the second BL group.

As illustrated in FIG. 27, the sequencer 15 executes a program operation. At this time, in a case where the data of the latch circuits BDL and CDL is “1”, the corresponding selected memory cell transistor MC is program inhibited. In addition, in a case where the data of at least one of the latch circuits BDL and CDL is “0”, the corresponding selected memory cell transistor MC is to be programmed. In the example illustrated in FIG. 27, the selected memory cell transistors MC corresponding to the Er1 and Er2 states are program inhibited. The selected memory cell transistors MC corresponding to the A1, A2, B1, B2, C1, and C2 states are to be programmed.

Next, the sequencer 15 executes the program verification operation for each BL group. That is, the program verification operations APV1, APV2, BPV1, BPV2, CPV1, and CPV1 are sequentially executed. In the program verification operation of each state, in a case where the selected memory cell transistor MC is an ON-cell, “0” data is stored in the sense circuit SA, and in a case where the selected memory cell transistor MC is an Off-cell, “1” data is stored in the sense circuit SA.

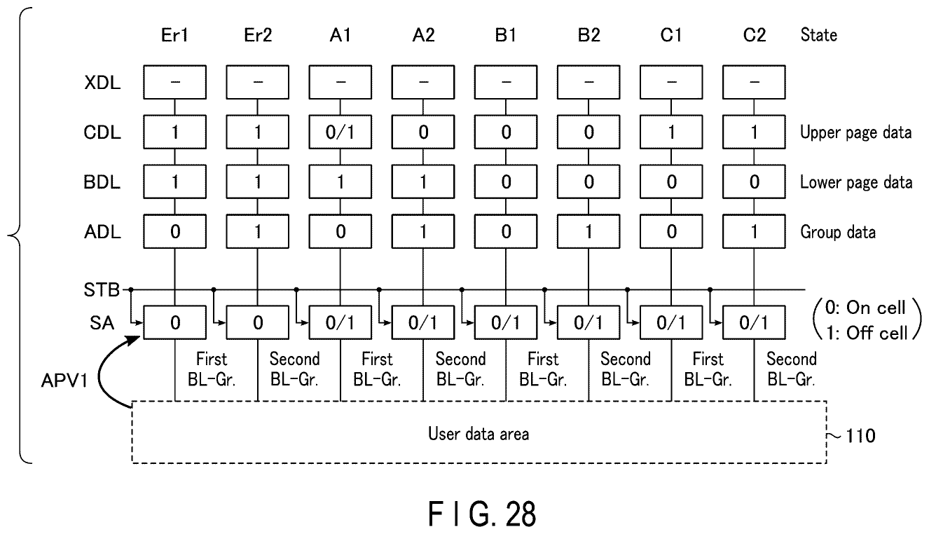

As illustrated in FIG. 28, more specifically, first, the sequencer 15 executes the program verification operation APV1 of the A1 state of the first BL group. In other words, the program verification operation APV1 using the verification voltage (VA−Δa) is executed. Each sense circuit SA stores data (0/1) read by the program verification operation APV1. The operation unit OP executes the operation of Expression (1) using the read data of the sense circuit SA, the group data of the latch circuit ADL, the Lower page data of the latch circuit BDL, and the Upper page data of the latch circuit CDL, and transfers the result to the latch circuit CDL.

CDL=(SA&~ADL&BDL&~CDL)|CDL (1)

As a result, in a case where “1” data is stored in the sense circuit SA corresponding to the A1 state (CDL/BDL/ADL=010), “1” data is stored in the corresponding latch circuit CDL. In a case where “0” data is stored in the sense circuit SA corresponding to the A1 state, “0” data is continuously stored in the corresponding latch circuit CDL. That is, “1” data is stored in the latch circuit CDL corresponding to the selected memory cell transistor MC whose threshold voltage has reached the target level among the plurality of selected memory cell transistors MC corresponding to the A1 state. Since the data of both the latch circuits BDL and CDL is “1”, the corresponding selected memory cell transistor MC is program inhibited in the next program loop (program operation).

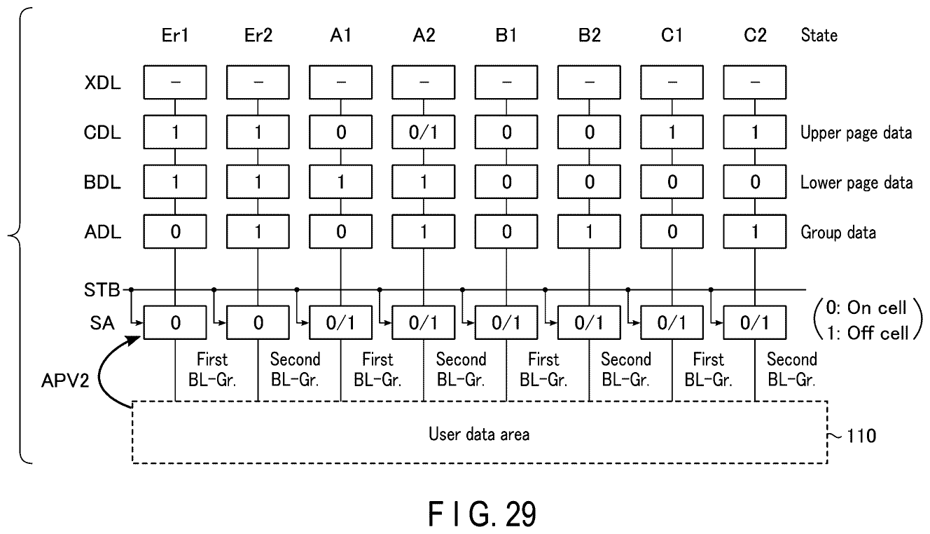

As illustrated in FIG. 29, next, the sequencer 15 executes the program verification operation APV2 of the A2 state of the second BL group. In other words, the program verification operation APV2 using the verification voltage VA is executed. The sense circuit SA stores the data (0/1) read by the program verification operation APV2. The operation unit OP executes the operation of Expression (2) using the read data of the sense circuit SA, the group data of the latch circuit ADL, the Lower page data of the latch circuit BDL, and the Upper page data of the latch circuit CDL, and transfers the result to the latch circuit CDL.

CDL=(SA&ADL&BDL&~CDL)|CDL (2)

As a result, in a case where “1” data is stored in the sense circuit SA corresponding to the A2 state (CDL/BDL/ADL=011), “1” data is stored in the corresponding latch circuit CDL. In a case where “0” data is stored in the sense circuit SA corresponding to state A2, “0” data is continuously stored in the corresponding latch circuit CDL. That is, “1” data is stored in the latch circuit CDL corresponding to the selected memory cell transistor MC whose threshold voltage has reached the target level among the plurality of selected memory cell transistors MC corresponding to the A2 state. Since the data of both the latch circuits BDL and CDL is “1”, the corresponding selected memory cell transistor MC is program inhibited in the next program loop (program operation).

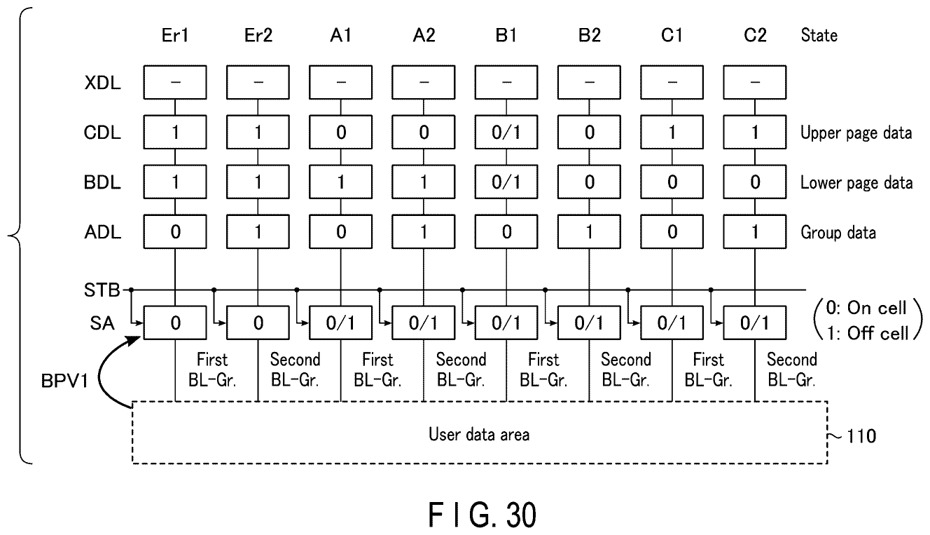

As illustrated in FIG. 30, next, the sequencer 15 executes the program verification operation BPV1 of the B1 state of the first BL group. In other words, the program verification operation BPV1 using the verification voltage (VB−Δb) is executed. The sense circuit SA stores the data (0/1) read by the program verification operation BPV1. The operation unit OP executes the operations of Expressions (3) and (4) using the read data of the sense circuit SA, the group data of the latch circuit ADL, the Lower page data of the latch circuit BDL, and the Upper page data of the latch circuit CDL, and transfers the results to the latch circuits BDL and CDL.

BDL=(SA&~ADL&~BDL&~CDL)|BDL (3)

CDL=(SA&~ADL&~BDL&~CDL)|CDL (4)

As a result, in a case where “1” data is stored in the sense circuit SA corresponding to the B1 state (CDL/BDL/ADL=000), “1” data is stored in the corresponding latch circuits BDL and CDL. In a case where “0” data is stored in the sense circuit SA corresponding to the B1 state, “0” data is continuously stored in the corresponding latch circuits BDL and CDL. That is, “1” data is stored in the latch circuits BDL and CDL corresponding to the selected memory cell transistor MC whose threshold voltage has reached the target level among the plurality of selected memory cell transistors MC corresponding to the B1 state. Since the data of both the latch circuits BDL and CDL is “1”, the corresponding selected memory cell transistor MC is program inhibited in the next program loop (program operation).

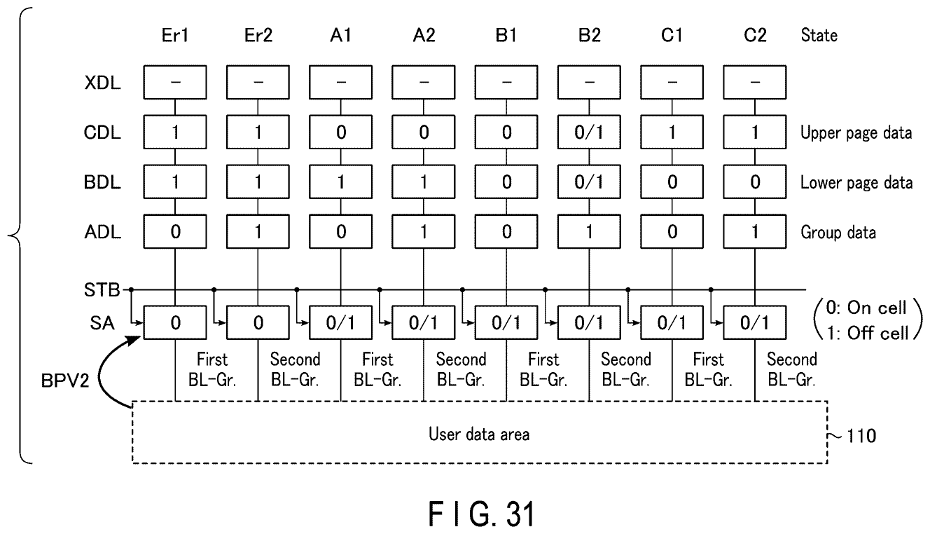

As illustrated in FIG. 31, next, the sequencer 15 executes the program verification operation BPV2 of the B2 state of the second BL group. In other words, the program verification operation BPV2 using the verification voltage VB is executed. The sense circuit SA stores the data (0/1) read by the program verification operation BPV2. The operation unit OP executes the operations of Expressions (5) and (6) using the read data of the sense circuit SA, the group data of the latch circuit ADL, the Lower page data of the latch circuit BDL, and the Upper page data of the latch circuit CDL, and transfers the results to the latch circuits BDL and CDL.

BDL=(SA&ADL&~BDL&~CDL)|BDL (5)

CDL=(SA&ADL&~BDL&~CDL)|CDL (6)

As a result, in a case where “1” data is stored in the sense circuit SA corresponding to the B2 state (CDL/BDL/ADL=001), “1” data is stored in the corresponding latch circuits BDL and CDL. In a case where “0” data is stored in the sense circuit SA corresponding to the B2 state, “0” data is continuously stored in the corresponding latch circuits BDL and CDL. That is, “1” data is stored in the latch circuits BDL and CDL corresponding to the selected memory cell transistor MC whose threshold voltage has reached the target level among the plurality of selected memory cell transistors MC corresponding to the B2 state. Since the data of both the latch circuits BDL and CDL is “1”, the corresponding selected memory cell transistor MC is program inhibited in the next program loop (program operation).

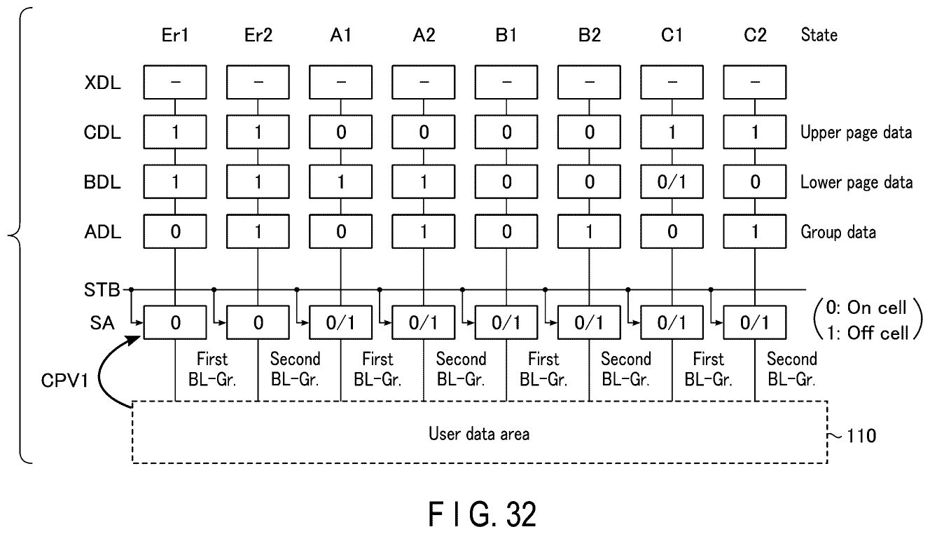

As illustrated in FIG. 32, next, the sequencer 15 executes the program verification operation CPV1 of the C1 state of the first BL group. In other words, the program verification operation CPV1 using the verification voltage (VC−Δc) is executed. The sense circuit SA stores the data (0/1) read by the program verification operation CPV1. The operation unit OP executes the operation of Expression (7) using the read data of the sense circuit SA, the group data of the latch circuit ADL, the Lower page data of the latch circuit BDL, and the Upper page data of the latch circuit CDL, and transfers the result to the latch circuit BDL.

BDL=(SA&~ADL&~BDL&CDL)|BDL (7)

As a result, in a case where “1” data is stored in the sense circuit SA corresponding to the C1 state (CDL/BDL/ADL=100), “1” data is stored in the corresponding latch circuit BDL. In a case where “0” data is stored in the sense circuit SA corresponding to the C1 state, “0” data is continuously stored in the corresponding latch circuit BDL. That is, “1” data is stored in the latch circuit BDL corresponding to the selected memory cell transistor MC whose threshold voltage has reached the target level among the plurality of selected memory cell transistors MC corresponding to the C1 state. Since the data of both the latch circuits BDL and CDL is “1”, the corresponding selected memory cell transistor MC is program inhibited in the next program loop (program operation).

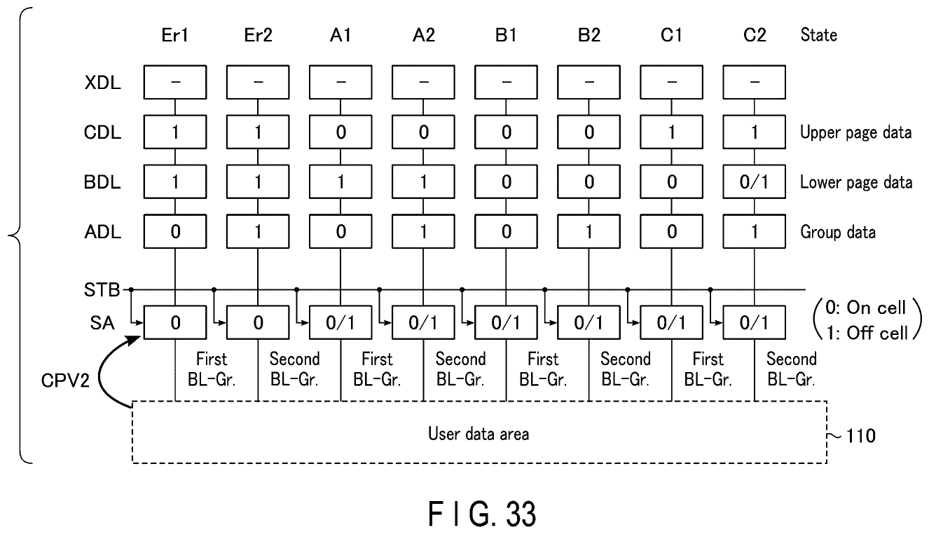

As illustrated in FIG. 33, next, the sequencer 15 executes the program verification operation CPV2 of the C2 state of the second BL group. In other words, the program verification operation CPV2 using the verification voltage VC is executed. The sense circuit SA stores the data (0/1) read by the program verification operation CPV2. The operation unit OP executes the operation of Expression (8) using the read data of the sense circuit SA, the group data of the latch circuit ADL, the Lower page data of the latch circuit BDL, and the Upper page data of the latch circuit CDL, and transfers the result to the latch circuit BDL.

BDL=(SA&ADL&~BDL&CDL)|BDL (8)

As a result, in a case where “1” data is stored in the sense circuit SA corresponding to the C2 state (CDL/BDL/ADL=101), “1” data is stored in the corresponding latch circuit BDL. In a case where “0” data is stored in the sense circuit SA corresponding to the C2 state, “0” data is continuously stored in the corresponding latch circuit BDL. That is, “1” data is stored in the latch circuit BDL corresponding to the selected memory cell transistor MC whose threshold voltage has reached the target level among the plurality of selected memory cell transistors MC corresponding to the C2 state. Since the data of both the latch circuits BDL and CDL is “1”, the corresponding selected memory cell transistor MC is program inhibited in the next program loop (program operation).

### 1.7 Effects According to Present Embodiment

With the configuration according to the present embodiment, it is possible to provide a memory system capable of improving the processing capability of the write operation. Hereinafter, the present effect will be described in detail.

For example, in a case where the sizes (gate length, gate width, etc.) of the plurality of memory cell transistors MC included in one cell unit CU are different for each layer L, the increase amount of the threshold voltage is different by one program operation depending on the size. In a case where the same verification voltage VA is set for the memory cell transistors MC having different write speeds (layers L), the program loop tends to increase due to the influence of the memory cell transistor MC in which writing is slow. That is, the processing time of the write operation is long, and the processing capability decreases.

On the other hand, with the configuration according to the present embodiment, the bit lines BL can be grouped for each layer L, and different verification conditions can be set for each BL group. That is, different verification voltages can be set for each layer L. Since the verification voltage can be optimized for each layer L, an increase in the number of program loops can be suppressed.

As a result, an increase in the processing time of the write operation can be suppressed. Therefore, the processing capability of the write operation can be improved.

Furthermore, with the configuration according to the present embodiment, the grouping of the BL group can be changed by changing the group mode (group data). Therefore, in a case where the characteristics (write speed) of the memory cell transistor MC vary due to variations in processing characteristics, the grouping of the BL group can be changed.

### 1.8 Modifications of First Embodiment

Next, a modification of the first embodiment will be described. In the present modification, a case where the sense time of the node SEN in the sense circuit SA is changed instead of changing the verification voltage as the verification condition for each BL group will be described. Hereinafter, differences from the first embodiment will be mainly described.

### 1.8.1 Relationship Between Voltage of Node SEN and Sense Time in Program Verification Operation

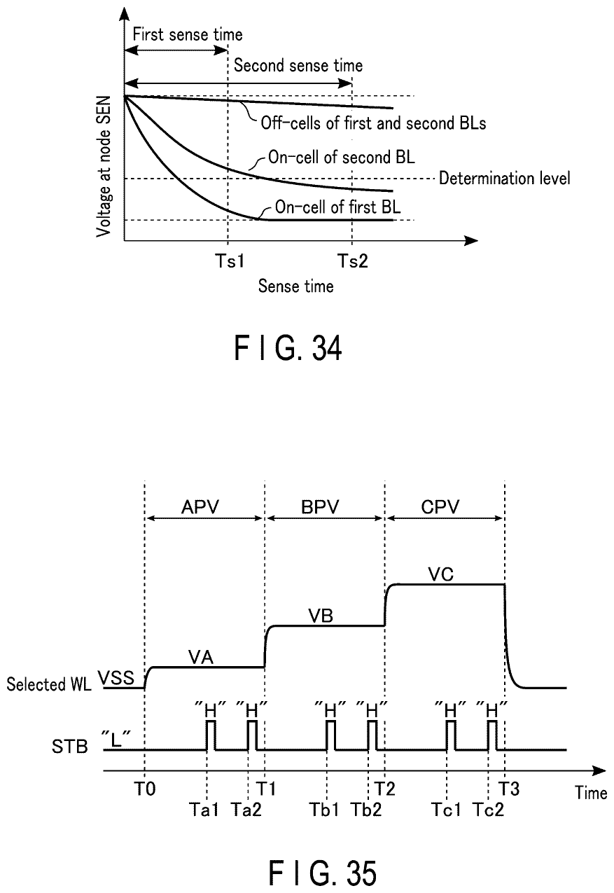

First, the relationship between the voltage of the node SEN and the sense time in the program verification operation will be described with reference to FIG. 34. FIG. 34 is a graph illustrating the relationship between the voltage of the node SEN and the sense time in the program verification operation. The example shown in FIG. 34 shows a case where the threshold voltage of the memory cell transistor MC of the first BL group is lower than the threshold voltage of the memory cell transistor MC of the second BL group.

As illustrated in FIG. 34, for example, in the program verification operation, in the node SEN corresponding to the ON-cell, the precharged charge is discharged via the bit line BL during the period in which the transistor T3 is turned on (hereinafter, referred to as a “sense time”). The rate at which the voltage of the node SEN decreases differs depending on the threshold voltage of the memory cell transistor MC. For example, the ON-cell of the first BL group having a low threshold voltage is set to the ON state stronger than the ON-cell of the second BL group having a high threshold voltage. Therefore, the voltage of the node SEN corresponding to the ON-cell of the first BL group decreases more rapidly than the voltage of the node SEN corresponding to the ON-cell of the second BL group. In the case of the Off-cell, the voltage of the node SEN hardly decreases regardless of the first and second BL groups.

Based on this relationship, the first sense time Ts1 and the second sense time Ts2 are set. The first sense time Ts1 is a time for determining whether the memory cell transistor MC of the first BL group is the ON-cell or the Off-cell. The second sense time Ts2 is a time for determining whether the memory cell transistor MC of the second BL group is the ON-cell or the Off-cell. The first sense time Ts1 and the second sense time Ts2 have a relationship of Ts1<Ts2. By executing the strobe operation corresponding to the sense time Ts1 and the strobe operation corresponding to the sense time Ts2, the verification determination of the first BL group and the verification determination corresponding to the second BL group can be executed using the same verification voltage.

### 1.8.2 Voltages of Selected Word Line and Control Signal STB in Program Verification Operation

Next, an example of the voltages of the selected word line WL and the control signal STB in the program verification operation will be described with reference to FIG. 35. FIG. 35 is a timing chart illustrating an example of the voltages of the selected word line WL and the control signal STB in the program verification operation.

As illustrated in FIG. 35, during the period from the time T0 to the time T1, the program verification operation APV of the A state is executed. More specifically, during the period from the time T0 to the time T1, the verification voltage VA is applied to the selected word line WL. In this state, at the time Ta1, the control signal STB is set to the “H” level. At this time, a strobe operation (corresponding to the program verification operation APV1) corresponding to the first BL group (first sense time Ts1) is executed. Next, at the time Ta2, the control signal STB is set to the “H” level. At this time, a strobe operation (corresponding to the program verification operation APV2) corresponding to the second BL group (second sense time Ts2) is executed.

During the period from the time T1 to the time T2, the program verification operation BPV of the B state is executed. More specifically, during the period from the time T1 to the time T2, the verification voltage VB is applied to the selected word line WL. In this state, at the time Tb1, the control signal STB is set to the “H” level. At this time, a strobe operation (corresponding to the program verification operation BPV1) corresponding to the first BL group (first sense time Ts1) is executed. Next, at the time Tb2, the control signal STB is set to the “H” level. At this time, a strobe operation (corresponding to the program verification operation BPV2) corresponding to the second BL group (second sense time Ts2) is executed.

During the period from the time T2 to the time T3, the program verification operation CPV of the C state is executed. More specifically, during the period from the time T2 to the time T3, the verification voltage VC is applied to the selected word line WL. In this state, at the time Tc1, the control signal STB is set to the “H” level. At this time, a strobe operation (corresponding to the program verification operation CPV1) corresponding to the first BL group (first sense time Ts1) is executed. Next, at the time Tc2, the control signal STB is set to the “H” level. At this time, a strobe operation (corresponding to the program verification operation CPV2) corresponding to the second BL group (second sense time Ts2) is executed.

### 1.8.3 Effects According to Present Modification

With the configuration according to the present modification, effects similar to those of the first embodiment can be obtained.

Furthermore, with the configuration according to the present modification, the program verification operation for each BL group can be executed by applying one verification voltage to one state. As a result, it is possible to suppress an increase in processing time due to application of different verification voltages to the selected word line WL for each BL group.

### 2. Second Embodiment

Next, a second embodiment will be described. In the second embodiment, a program verification operation different from that of the first embodiment will be described. In the second embodiment, the group data is discarded, and a plurality of control signals STB corresponding to each BL group is provided. Accordingly, in the second embodiment, the program verification operation for each BL group is controlled by the plurality of control signals STB. Hereinafter, differences from the first embodiment will be mainly described.

### 2.1 Configuration of Sense Amplifier Module and Data Register

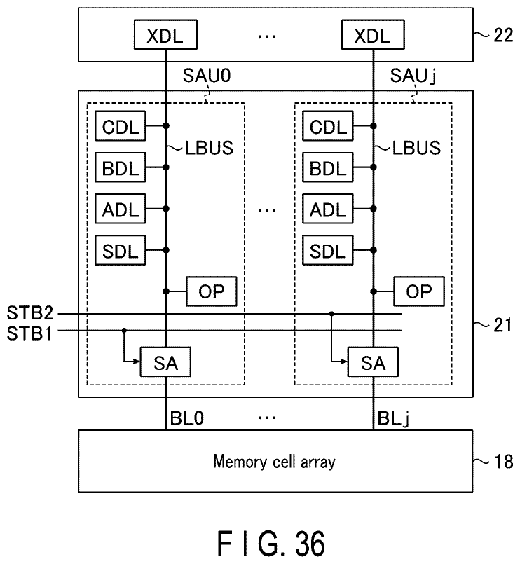

First, an example of a configuration of the sense amplifier module 21 and the data register 22 will be described with reference to FIG. 36. FIG. 36 is a block diagram illustrating an example of a configuration of the sense amplifier module 21 and the data register 22.

As illustrated in FIG. 36, the sense amplifier unit SAU includes a sense circuit SA, an operation unit OP, and latch circuits SDL, ADL, BDL, and CDL, as in the description of the first embodiment with reference to FIG. 10. The coupling of the operation unit OP and the latch circuits SDL, ADL, BDL, and CDL is similar to that of the first embodiment.

In the present embodiment, different control signals STB are provided for each BL group. More specifically, for example, a control signal STB1 corresponds to the first group. A control signal SBT2 corresponds to the second BL group.

For example, the bit line BL0 is included in the first BL group. The sense circuit SA of the sense amplifier unit SAU0 to which the bit line BL0 is coupled receives the control signal STB1. In addition, for example, the bit line BLj is included in the second BL group. The sense circuit SA of the sense amplifier unit SAUj to which the bit line BLj is coupled receives the control signal STB2.

In the sense amplifier unit SAU corresponding to the first BL group, the strobe operation is executed based on the control signal STB1. On the other hand, in the sense amplifier unit SAU corresponding to the second BL group, the strobe operation is executed based on the control signal STB2. The sequencer 15 executes the program verification operation for each BL group under the control of the control signals STB1 and STB2.

### 2.2 Voltage of Selected Word Line and Control Signal STB in Program Verification Operation

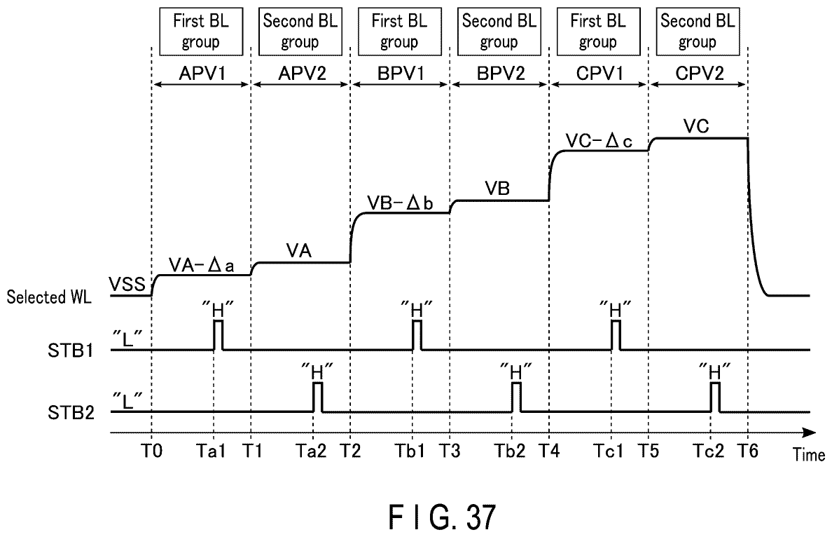

Next, an example of the voltages of the selected word line WL and the control signals STB1 and STB2 in the program verification operation will be described with reference to FIG. 37. FIG. 37 is a timing chart illustrating an example of the voltages of the selected word line WL and the control signals STB1 and STB2 in the program verification operation.

As illustrated in FIG. 37, during the period from the time T0 to the time T1, the program verification operation APV1 of the A1 state of the first BL group is executed. More specifically, during the period from the time T0 to the time T1, the verification voltage VA−Δa is applied to the selected word line WL. In this state, at the time Ta1, the control signal STB1 is set to the “H” level, and the strobe operation is executed.

During the period from the time T1 to the time T2, the program verification operation APV2 of the A2 state of the second BL group is executed. More specifically, during the period from the time T1 to the time T2, the verification voltage VA is applied to the selected word line WL. In this state, at the time Ta2, the control signal STB2 is set to the “H” level, and the strobe operation is executed.

During the period from the time T2 to the time T3, the program verification operation BPV1 of the B1 state of the first BL group is executed. More specifically, during the period from the time T2 to the time T3, the verification voltage VB−Δb is applied to the selected word line WL. In this state, at the time Tb1, the control signal STB1 is set to the “H” level, and the strobe operation is executed.

During the period from the time T3 to the time T4, the program verification operation BPV2 of the B2 state of the second BL group is executed. More specifically, during the period from the time T3 to the time T4, the verification voltage VB is applied to the selected word line WL. In this state, at the time Tb2, the control signal STB2 is set to the “H” level, and the strobe operation is executed.

During the period from time T4 to time T5, the program verification operation CPV1 of the C1 state of the first BL group is executed. More specifically, during the period from time T4 to time T5, the verification voltage VC−Δc is applied to the selected word line WL. In this state, at the time Tc1, the control signal STB1 is set to the “H” level, and the strobe operation is executed.

During the period from time T5 to time T6, the program verification operation CPV2 of the C2 state of the second BL group is executed. More specifically, during the period from time T5 to time T6, the verification voltage VC is applied to the selected word line WL. In this state, at the time Tc2, the control signal STB2 is set to the “H” level, and the strobe operation is executed.

### 2.3 Flow of Write Operation

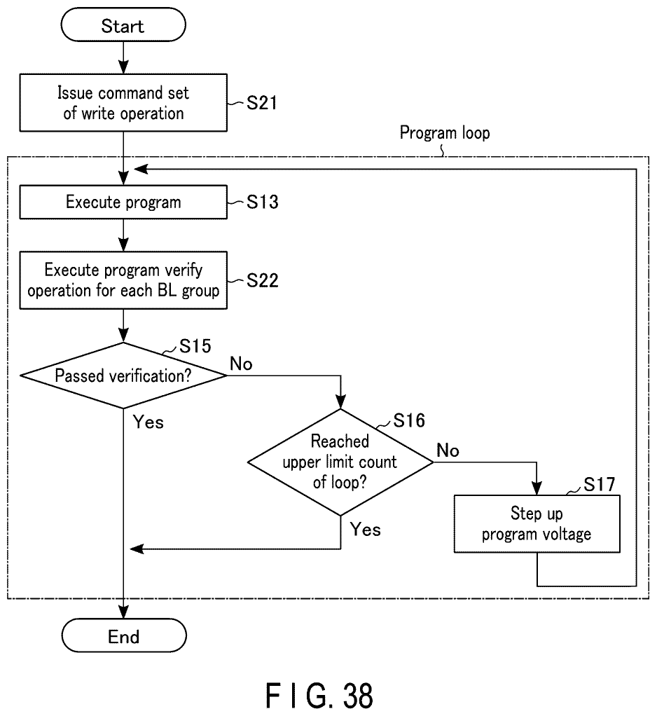

Next, a flow of the write operation will be described with reference to FIG. 38. FIG. 38 is a flowchart illustrating a flow of the write operation.

As shown in FIG. 38, upon receiving a write request from the host 2, the CPU 230 issues a command set for a write operation (S21). The command set of the present embodiment includes a command indicating that the program verification operation is executed using the plurality of control signals STB, a command of the write operation, an address of the user data area 110 to which the write data is written, and the write data. A command sequence of the write operation will be described later. The CPU 230 transmits the issued command set to the memory device 100.

Upon receiving the command set, the sequencer 15 starts a program loop. More specifically, the sequencer 15 first executes a program operation (S13). At this time, a program voltage is applied to the selected word line WL.

After the program operation is ended, the sequencer 15 executes the program verification operation for each BL group based on the control signals STB (S22). The sequencer 15 controls different control signals STB for each BL group to execute the program verification operation.

The operation of steps S15 to S17 is similar to that in the description of the first embodiment with reference to FIG. 17.

### 2.4 Command Sequence of Write Operation

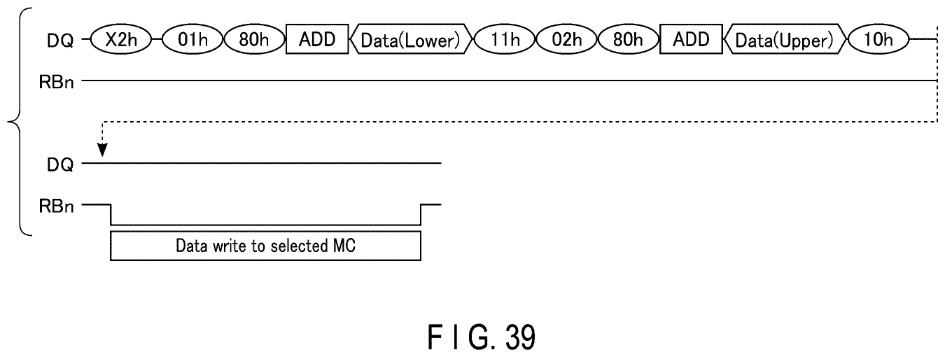

Next, an example of a command sequence of the write operation will be described with reference to FIG. 39. FIG. 39 is a diagram illustrating an example of a command sequence of the write operation.

As illustrated in FIG. 39, first, the memory controller 200 transmits a command “X2 h” to the memory device 100. The command “X2 h” is a prefix command indicating the program verification operation using the plurality of control signals STB (STB1 and STB2). Next, the memory controller 200 transmits commands “01 h” and “80 h”, an address “ADD”, and the Lower page data to the memory device 100, as in the description of the first embodiment using FIG. 18. The Lower page data is stored in the plurality of latch circuits XDL.

Next, the memory controller 200 transmits a command “11 h” to the memory device 100. Upon receiving the command “11 h”, the sequencer 15 transfers the Lower page data (Lower bit) of the latch circuits XDL to, for example, the latch circuits BDL.

Next, the memory controller 200 transmits commands “02 h” and “80 h”, the address “ADD”, and the Upper page data to the memory device 100. The Upper page data is stored in the plurality of latch circuits XDL.

Next, the memory controller 200 transmits a command “10 h” to the memory device 100. Upon receiving the command “10 h”, the sequencer 15 transfers the Upper page data (Upper bit) of the latch circuits XDL to, for example, the latch circuits CDL. Next, the sequencer 15 sets the ready/busy signal RBn to the “L” level. Then, the sequencer 15 repeats a program loop to write data in the selected memory cell transistors MC. In a case where the write operation is ended, the sequencer 15 sets the ready/busy signal RBn to the “H” level.

### 2.5 Specific Example of Program Verification Operation

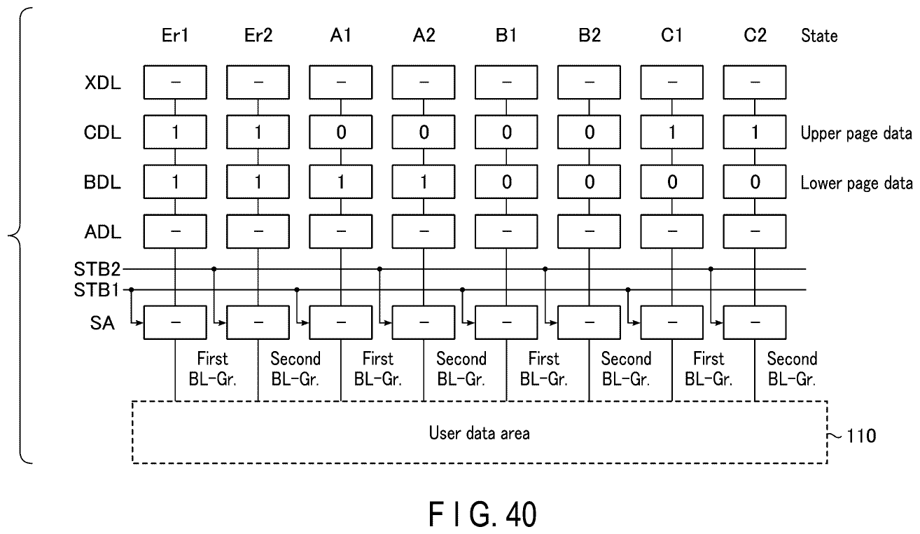

Next, a specific example of the program verification operation will be described with reference to FIGS. 40 to 46. FIGS. 40 to 46 are diagrams illustrating an example of states of the latch circuits at the time of the write operation. In the examples illustrated in FIGS. 40 to 46, the operation unit OP and the latch circuit SDL are omitted.

As illustrated in FIG. 40, in the present specific example, each sense circuit SA corresponding to the Er1, A1, B1, or C1 state is coupled to the bit line BL of the first BL group. Each sense circuit SA corresponding to the Er2, A2, B2, or C2 state is coupled to the bit line BL of the second BL group. Data of the Er1, A1, B1, or C1 states is written to the selected memory cell transistors MC corresponding to the bit lines BL of the first BL group. Data of the Er2, A2, B2, or C2 states is written to the selected memory cell transistors MC corresponding to the bit lines BL of the second BL group.

As in the first embodiment, the Lower page data and the Upper page data are stored in the latch circuits BDL and CDL, respectively. In the present embodiment, since the user data is discarded, the valid data is not stored in the latch circuit ADL.

In this state, the sequencer 15 executes the program operation. At this time, in a case where the data of the latch circuits BDL and CDL is “1”, the corresponding selected memory cell transistor MC is program inhibited. In addition, in a case where the data of at least one of the latch circuits BDL and CDL is “0”, the corresponding selected memory cell transistor MC is to be programmed. In the example illustrated in FIG. 40, the selected memory cell transistor MC corresponding to the Er1 and Er2 states is program inhibited. The selected memory cell transistors MC corresponding to the A1, A2, B1, B2, C1, and C2 states are to be programmed.

Next, the sequencer 15 executes the program verification operation for each BL group. That is, the program verification operations APV1, APV2, BPV1, BPV2, CPV1, and CPV1 are sequentially executed. In the strobe operation of each state, in a case where the control signal STB1 is at the “H” level, “0” or “1” data is stored in the sense circuit SA corresponding to the first BL group, and in a case where the control signal STB2 is at the “H” level, “0” or “1” data is stored in the sense circuit SA corresponding to the second BL group.

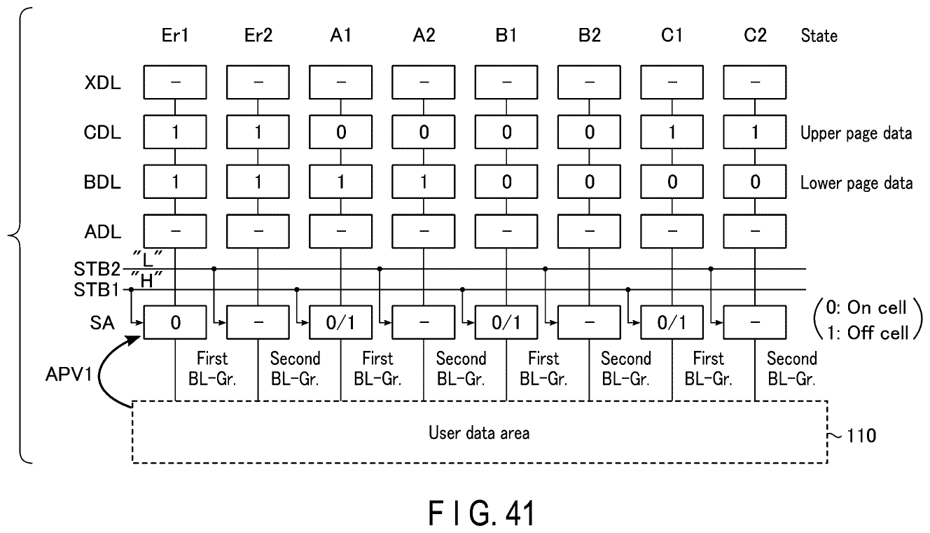

As illustrated in FIG. 41, more specifically, first, the sequencer 15 executes the program verification operation APV1 of the A1 state of the first BL group. In other words, the program verification operation APV1 using the verification voltage (VA−Δa) is executed. In the strobe operation, the control signal STB1 is set to the “H” level, and the control signal STB2 is set to the “L” level. The data (0/1) read by the program verification operation APV1 is stored in each sense circuit SA corresponding to the first BL group.

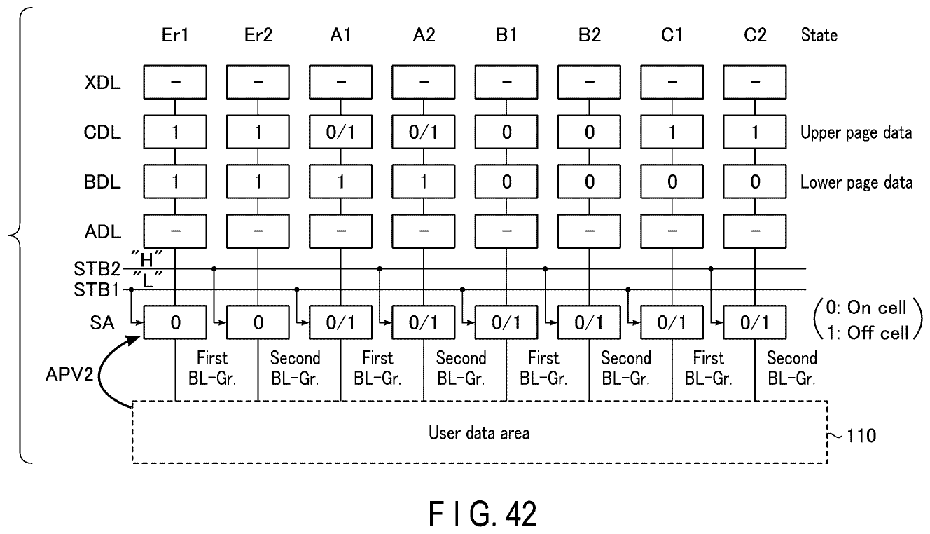

As illustrated in FIG. 42, next, the sequencer 15 executes the program verification operation APV2 of the A2 state of the second BL group. In other words, the program verification operation APV2 using the verification voltage VA is executed. In the strobe operation, the control signal STB1 is set to the “L” level, and the control signal STB2 is set to the “H” level. The data (0/1) read by the program verification operation APV2 is stored in each sense circuit SA corresponding to the second BL group.

In the present embodiment, the arithmetic expression corresponding to the A state of each BL group is the same. Therefore, the operation units OP corresponding to the respective BL groups collectively execute the arithmetic processing corresponding to the A state. The operation unit OP executes the operation of Expression (9) using the read data of the sense circuit SA, the Lower page data of the latch circuit BDL, and the Upper page data of the latch circuit CDL, and transfers the result to the latch circuit CDL.

CDL=(SA&BDL&~CDL)|CDL (9)

As a result, in a case where “1” data is stored in the sense circuit SA corresponding to the A1 or A2 state (CDL/BDL=01), “1” data is stored in the corresponding latch circuit CDL. In a case where “0” data is stored in the sense circuit SA corresponding to the A1 or A2 state, “0” data is continuously stored in the corresponding latch circuit CDL. That is, “1” data is stored in the latch circuit CDL corresponding to the selected memory cell transistor MC whose threshold voltage has reached the target level among the plurality of selected memory cell transistors MC corresponding to the A1 and A2 states. Since the data of both the latch circuits BDL and CDL is “1”, the corresponding selected memory cell transistor MC is program inhibited in the next program loop (program operation).

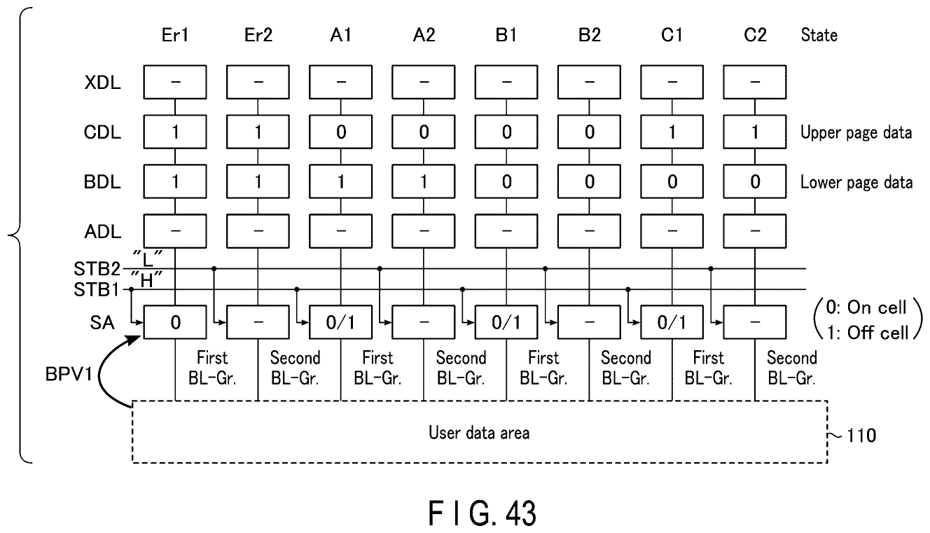

As illustrated in FIG. 43, more specifically, first, the sequencer 15 executes the program verification operation BPV1 of the B1 state of the first BL group. In other words, the program verification operation BPV1 using the verification voltage (VB−Δb) is executed. In the strobe operation, the control signal STB1 is set to the “H” level, and the control signal STB2 is set to the “L” level. The data (0/1) read by the program verification operation BPV1 is stored in each sense circuit SA corresponding to the first BL group.

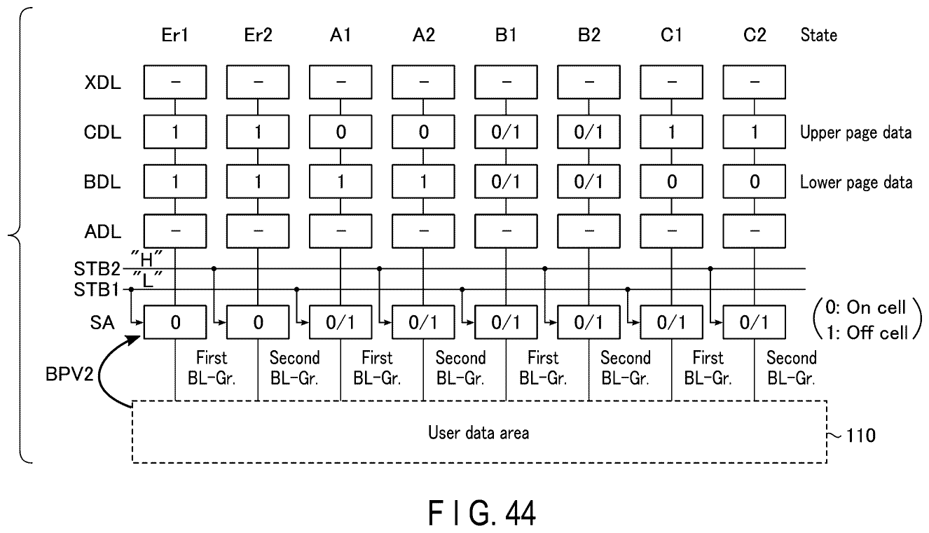

As illustrated in FIG. 44, next, the sequencer 15 executes the program verification operation BPV2 of the B2 state of the second BL group. In other words, the program verification operation BPV2 using the verification voltage VB is executed. In the strobe operation, the control signal STB1 is set to the “L” level, and the control signal STB2 is set to the “H” level. The data (0/1) read by the program verification operation BPV2 is stored in each sense circuit SA corresponding to the second BL group.

In the present embodiment, the arithmetic expression corresponding to the B state of each BL group is the same. Therefore, the operation units OP corresponding to the respective BL groups collectively execute the arithmetic processing corresponding to the B state. The operation unit OP executes the operations of Expressions (10) and (11) using the read data of the sense circuit SA, the Lower page data of the latch circuit BDL, and the Upper page data of the latch circuit CDL, and transfers the results to the latch circuits BDL and CDL.

BDL=(SA&~BDL&~CDL)|BDL (10)

CDL=(SA&~BDL&~CDL)|CDL (11)

As a result, in a case where “1” data is stored in the sense circuit SA corresponding to the B1 or B2 state (CDL/BDL=00), “1” data is stored in the corresponding latch circuits BDL and CDL. In a case where “0” data is stored in the sense circuit SA corresponding to the B1 or B2 state, “0” data is continuously stored in the corresponding latch circuits BDL and CDL. That is, “1” data is stored in the latch circuits BDL and CDL corresponding to the selected memory cell transistor MC whose threshold voltage has reached the target level among the plurality of selected memory cell transistors MC corresponding to the B1 and B2 states. Since the data of both the latch circuits BDL and CDL is “1”, the corresponding selected memory cell transistor MC is program inhibited in the next program loop (program operation).

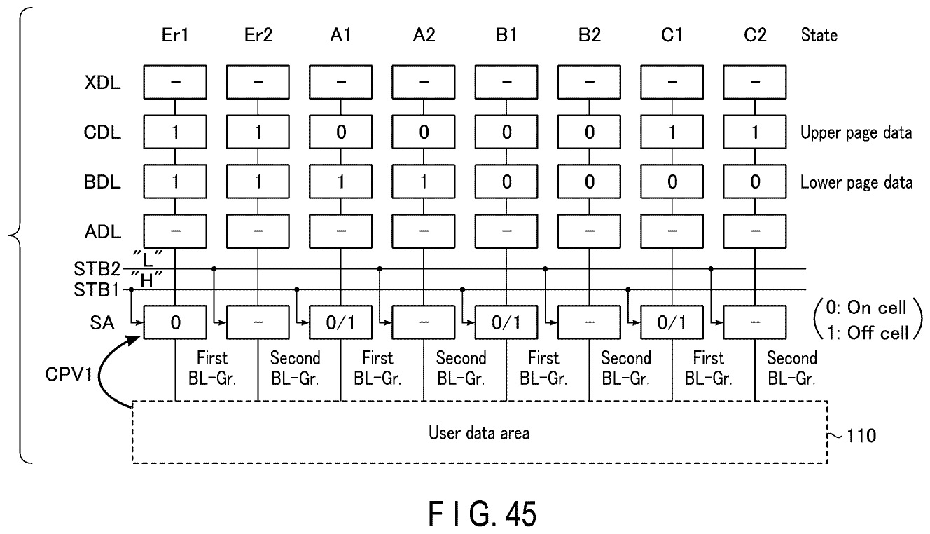

As illustrated in FIG. 45, more specifically, first, the sequencer 15 executes the program verification operation CPV1 of the C1 state of the first BL group. In other words, the program verification operation CPV1 using the verification voltage (VC−Δc) is executed. In the strobe operation, the control signal STB1 is set to the “H” level, and the control signal STB2 is set to the “L” level. The data (0/1) read by the program verification operation CPV1 is stored in each sense circuit SA corresponding to the first BL group.

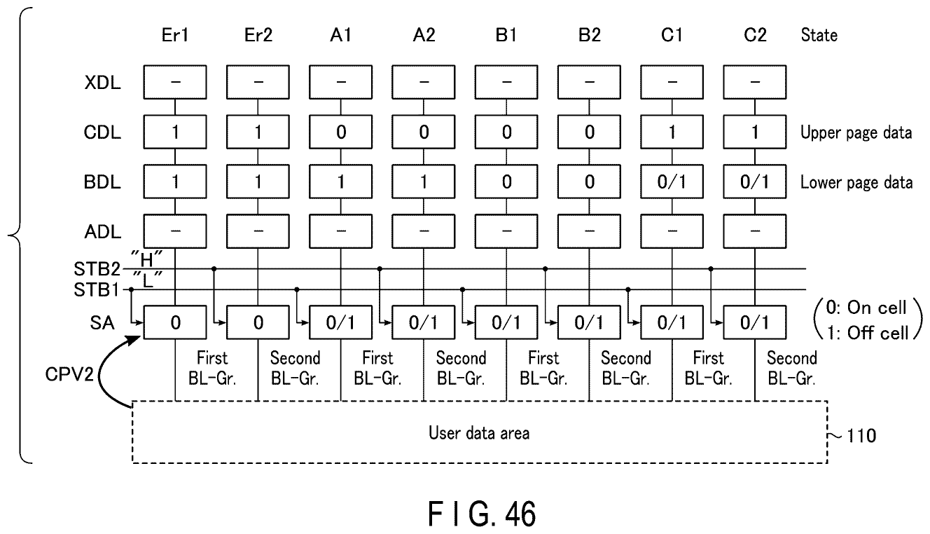

As illustrated in FIG. 46, next, the sequencer 15 executes the program verification operation CPV2 of the C2 state of the second BL group. In other words, the program verification operation CPV2 using the verification voltage VC is executed. In the strobe operation, the control signal STB1 is set to the “L” level, and the control signal STB2 is set to the “H” level. The data (0/1) read by the program verification operation CPV2 is stored in each sense circuit SA corresponding to the second BL group.

In the present embodiment, the arithmetic expression corresponding to the C state of each BL group is the same. Therefore, the operation units OP corresponding to the respective BL groups collectively execute the arithmetic processing corresponding to the C state. The operation unit OP executes the operation of Expression (12) using the read data of the sense circuit SA, the Lower page data of the latch circuit BDL, and the Upper page data of the latch circuit CDL, and transfers the result to the latch circuit BDL.

BDL=(SA&~BDL&CDL)|BDL (12)

As a result, in a case where “1” data is stored in the sense circuit SA corresponding to the C1 or C2 state (CDL/BDL=10), “1” data is stored in the corresponding latch circuit BDL. In a case where “0” data is stored in the sense circuit SA corresponding to the C1 or C2 state, “0” data is continuously stored in the corresponding latch circuit BDL. That is, “1” data is stored in the latch circuit BDL corresponding to the selected memory cell transistor MC whose threshold voltage has reached the target level among the plurality of selected memory cell transistors MC corresponding to the C1 and C2 states. Since the data of both the latch circuits BDL and CDL is “1”, the corresponding selected memory cell transistor MC is program inhibited in the next program loop (program operation).

### 2.6 Effects According to Present Embodiment

With the configuration according to the present embodiment, effects similar to those of the first embodiment can be obtained.

Furthermore, with the configuration according to the present embodiment, the program verification operation for each BL group can be executed by providing different control signals STB for each BL group. As a result, it is not necessary to provide a latch circuit that stores the group data of the BL group in the sense amplifier unit SAU. Therefore, an increase in the number of latch circuits in the sense amplifier unit SAU can be suppressed.

Furthermore, with the configuration according to the present embodiment, the strobe operation can be executed at different timings for each BL group for one state, and the arithmetic processing in the operation unit OP can be collectively executed in all BL groups.

### 2.7 Modification of Second Embodiment

Next, a modification of the second embodiment will be described. In the present modification, as in the modification of the first embodiment, a case where the sense time of the node SEN in the sense circuit SA is changed instead of changing the verification voltage as the verification condition for each BL group will be described. Hereinafter, differences from the second embodiment will be mainly described.

### 2.7.1 Voltages of Selected Word Line and Control Signals STB1 and STB2 in Program Verification Operation

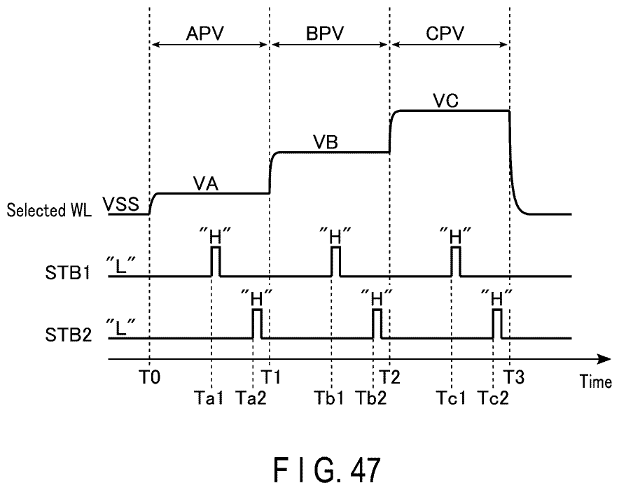

An example of the voltages of the selected word line WL and the control signals STB1 and STB2 in the program verification operation will be described with reference to FIG. 47. FIG. 47 is a timing chart illustrating an example of the voltages of the selected word line WL and the control signals STB1 and STB2 in the program verification operation.

As illustrated in FIG. 47, during the period from the time T0 to the time T1, the program verification operation APV of the A state is executed. More specifically, during the period from the time T0 to the time T1, the verification voltage VA is applied to the selected word line WL. In this state, at the time Ta1, the control signal STB1 is set to the “H” level. At this time, the strobe operation corresponding to the first BL group is executed. Next, at the time Ta2, the control signal STB2 is set to the “H” level. At this time, the strobe operation corresponding to the second BL group is executed.

During the period from the time T1 to the time T2, the program verification operation BPV of the B state is executed. More specifically, during the period from the time T1 to the time T2, the verification voltage VB is applied to the selected word line WL. In this state, at the time Tb1, the control signal STB1 is set to the “H” level. At this time, the strobe operation corresponding to the first BL group is executed. Next, at the time Tb2, the control signal STB2 is set to the “H” level. At this time, the strobe operation corresponding to the second BL group is executed.

During the period from the time T2 to the time T3, the program verification operation CPV of the C state is executed. More specifically, during the period from the time T2 to the time T3, the verification voltage VC is applied to the selected word line WL. In this state, the control signal STB1 is set to the “H” level at the time Tc1. At this time, the strobe operation corresponding to the first BL group is executed. Next, at the time Tc2, the control signal STB2 is set to the “H” level. At this time, the strobe operation corresponding to the second BL group is executed.

### 2.7.2 Effects According to Present Modification

With the configuration according to the present modification, effects similar to those of the second embodiment can be obtained.

Furthermore, with the configuration according to the present modification, the program verification operation for each BL group can be executed by applying one verification voltage to one state. As a result, it is possible to suppress an increase in processing time due to application of different verification voltages to the selected word line WL for each BL group.

### 3. Modifications and the Like

The memory system according to the above embodiments includes a memory device (100) and a memory controller (200) configured to control a write operation in the memory device. The memory device includes a memory cell array (18) including a first memory cell (MC) and a second memory cell (MC) stacked apart each other above a substrate, a word line (WL) coupled to a gate of the first memory cell and a gate of the second memory cell, a first bit line (BL0) coupled to the first memory cell, a second bit line (BL3) coupled to the second memory cell, and a sense amplifier module (21) to which the first bit line and the second bit line are coupled. The write operation includes a program operation and a program verification operation. In the program verification operation, a first verification voltage (VA−Δa) of a first state (A1 state) corresponding to a first group including the first bit line is smaller than a second verification voltage (VA) of the first state (A2 state) corresponding to a second group including the second bit line.

With the configuration according to the above embodiments, it is possible to provide a memory system capable of improving the processing capability of the write operation.

Note that the present invention is not limited to the above-described embodiments, and various modifications can be applied.

Furthermore, the “coupling” in the above embodiments includes a state in which the coupling is indirectly made with some unit, for example, a transistor or a resistor, interposed therebetween.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a memory device including:
a memory cell array including a first memory cell and a second memory cell stacked apart each other above a substrate;
a word line coupled to a gate of the first memory cell and a gate of the second memory cell;
a first bit line coupled to the first memory cell;
a second bit line coupled to the second memory cell; and
a sense amplifier module to which the first bit line and the second bit line are coupled; and
a memory controller configured to control a write operation in the memory device, wherein
the write operation includes a program operation and a program verification operation, and
in the program verification operation, a first verification voltage of a first state corresponding to a first group including the first bit line is smaller than a second verification voltage of the first state corresponding to a second group including the second bit line.

2. The memory system according to claim 1, wherein
an increase amount of a threshold voltage of the first memory cell by the program operation is smaller than an increase amount of a threshold voltage of the second memory cell.

3. The memory system according to claim 1, wherein
the first verification voltage and the second verification voltage are continuously applied to the word line in the program verification operation.

4. The memory system according to claim 1, wherein
a width of a threshold voltage distribution of the first state corresponding to the first group is smaller than a width of a threshold voltage distribution of the first state corresponding to the second group.

5. The memory system according to claim 1, wherein
in the program verification operation, during a period in which a first voltage is applied to the word line, data of the first memory cell and the second memory cell is read, and a first sense time for reading the data of the first memory cell is shorter than a second sense time for reading the data of the second memory cell.

6. The memory system according to claim 1, wherein
the write operation further includes a read operation of group data indicating the first group and the second group, and
the program operation and the program verification operation are executed after the read operation of the group data.

7. The memory system according to claim 6, wherein
in the write operation, the memory controller is further configured to:
issue a command set including a command indicating the read operation of the group data, an address of the group data, a command indicating the write operation, addresses of the first memory cell and the second memory cell, and write data; and
transmit the command set to the memory device.

8. The memory system according to claim 6, wherein
the sense amplifier module includes;
a first sense circuit to which the first bit line is coupled;
a second sense circuit to which the second bit line is coupled;
a first latch circuit and a second latch circuit coupled to the first sense circuit; and
a third latch circuit and a fourth latch circuit coupled to the second sense circuit, and
in the write operation, the group data is stored in the first latch circuit and the third latch circuit, and write data is stored in the second latch circuit and the fourth latch circuit.

9. The memory system according to claim 8, wherein
in the program verification operation, the second latch circuit is updated based on a result of a first arithmetic expression using at least data of the first sense circuit, the first latch circuit, and the second latch circuit.

10. The memory system according to claim 9, wherein
in the program verification operation, the fourth latch circuit is updated based on a result of a second arithmetic expression different from the first arithmetic expression using at least data of the second sense circuit, the third latch circuit, and the fourth latch circuit.

11. The memory system according to claim 8, wherein
the memory cell array further includes a first block and a second block,
the first block includes the first memory cell and the second memory cell, and
the second block stores the group data.

12. The memory system according to claim 1, wherein
a size of the first memory cell is different from a size of the second memory cell.

13. The memory system according to claim 1, wherein
the sense amplifier module includes:
a first sense circuit to which the first bit line and a first control signal line are coupled; and
a second sense circuit to which the second bit line and a second control signal line different from the first control signal line are coupled.

14. The memory system according to claim 8, wherein
in the program verification operation, the first sense circuit reads data of the first memory cell based on a first control signal, and the second sense circuit reads data of the second memory cell based on a second control signal different from the first control signal.

15. The memory system according to claim 14, wherein
in the program verification operation, the data of the first memory cell is read during a period in which the first verification voltage is applied to the word line, and the data of the second memory cell is read during a period in which the second verification voltage is applied to the word line.

16. The memory system according to claim 14, wherein
in the program verification operation, during a period in which a first voltage is applied to the word line, data of the first memory cell and the second memory cell is read, and a first sense time for reading the data of the first memory cell is shorter than a second sense time for reading the data of the second memory cell.

17. The memory system according to claim 14, wherein
in the write operation, the memory controller is further configured to:
issue a command set including a command indicating the program verification operation using the first control signal and the second control signal, a command indicating the write operation, addresses of the first memory cell and the second memory cell, and write data; and
transmit the command set to the memory device.

18. The memory system according to claim 1, wherein
data stored in each of the first memory cell and the second memory cell corresponds to one of 2ⁿ threshold voltage regions that include first threshold voltage region to 2ⁿth threshold voltage region whose regions are defined in ascending order of voltage where n is an integer of 2 or more, and
the first state corresponds to one of the second threshold voltage region to the 20th threshold voltage region.

19. The memory system according to claim 1, wherein
the memory device is a NAND flash memory.
